(19) United States
(12) Patent Application Publication
(10) Pub. No.: US 2004/0229443 A1
(43) Pub. Date: Nov. 18, 2004

(54) Structures, materials and methods for fabrication of nanostructures by transposed split of ion cut materials

(76) Inventor: Robert W. Bower, Incline Village, NV (US)

Correspondence Address: JOHN P. O'BANION, O'BANION & RITCHEY LLP, 400 CAPITOL MALL SUITE 1550, SACRAMENTO, CA, 95814, US

(21) Appl. No.: 10/763,578

(22) Filed: Jan. 21, 2004

Related U.S. Application Data
(63) Continuation-in-part of application No. 10/051,623, filed on Jan. 17, 2002.
Application No. 10/051,623 is a continuation of application No. 09/476,456, filed on Dec. 30, 1999, now Pat. No. 6,346,458.
(60) Provisional application No. 60/114,494, filed on Dec. 31, 1998.
(60) Provisional application No. 60/442,012, filed on Jan. 22, 2003.

(51) Int. Cl. H01L 21/30

(52) U.S. Cl. 438/455; 438/514

(57) ABSTRACT

Structures, materials and methods for resolving forward implantation skew in the transposed splitting of ion cut materials. By way of example a “material X” is described, such as in the form of a wafer or substrate, having a low resistivity device layer within which nanodevices can be fabricated, an insulation layer, a hydrogen getter layer (e.g., heavily doped region), and a diffusion layer. Devices fabricated in the device layer can be transferred by bonding the surface of the device layer to a target material and then injecting and diffusing hydrogen from the backside of material X through the diffusion layer to the hydrogen getter layer to form a weakened plane. A splitting process then separates the device layer from the remainder of the substrate. A method is also described for thermally isolating a device layer stack, or other target, from a heated diffusion layer when diffusing hydrogen to form the weakened plane.

### CROSS-REFERENCE TO RELATED APPLICATIONS

This application is a continuation-in-part of copending application Ser. No. 10/051,623 filed on Jan. 17, 2002, which is a continuation of Ser. No. 09/476,456, filed on Dec. 30, 1999, now U.S. Pat. No. 6,346,458, incorporated herein by reference in its entirety, which claims priority to U.S. provisional application serial No. 60/114,494, filed on Dec. 31, 1998, incorporated herein by reference in its entirety. Priority is claimed to each of the foregoing applications and patents. This application also claims priority from U.S. provisional application serial No. 60/442,012 filed on Jan. 22, 2003, incorporated herein by reference in its entirety.

### STATEMENT REGARDING FEDERALLY SPONSORED RESEARCH OR DEVELOPMENT

Not Applicable

### INCORPORATION-BY-REFERENCE OF MATERIAL SUBMITTED ON A COMPACT DISC

Not Applicable

### BACKGROUND OF THE INVENTION

1. Field of the Invention

This invention pertains generally to expunging material layers within a solid utilizing an ion split cut process, and more particularly to methods for resolving forward skew and enhancing the transfer of an expunged layer or layer to a target material.

2. Description of Related Art

The ion split cutting of material across a cutting plane weakened by injected and diffused atoms provides for the transfer of thin circuit layers to a target substrate, such as for building up multilayer three-dimensional nanostructures. Increasing interest has been generated in the ion split cut process as circuit densities and desired levels of integration are pushed farther.

One method of ion split cutting involves introducing atoms into solid materials at a first location and then diffusing the atoms to getter/acceptor centers (e.g., formed by introducing acceptors into a region of the material), such as those forming a cutting plane across the solid material. The resulting weakening at the cutting plane allows the solid material to be split, thereby providing a means for expunging a layer from a material, such as for removing a device layer. Methods for performing a transposed split of ion cut materials are generally described in U.S. Pat. No. 6,346,458 which is incorporated herein by reference.

One drawback to conventional processes for ion cutting materials is that a forward skew can arise in the implanted acceptor concentrations. The skew creates unwanted doping in the region of the forward skew and can interfere with the formation of the desired nanodevices.

Another drawback to conventional processes for ion cutting materials is the need in many cases to thin a substrate material prior to the creation of a cutting plane. The thinning step increases the cost of circuit fabrication.

A further drawback to conventional processes for ion cutting materials is the need for extended periods of heating during the process which not only extends the fabrication cycle but which can create damage to fabricated nanodevices. The damage problem becomes increasingly acute when stacks of joined layers are to be transferred. A common method of thinning and stacking chips without use of the transposed ion cut technology includes a method where a single crystal bulk material is first processed to form circuit nanostructures, then planarized and bonded to a 3-d stack with j-1 layers. Then the bulk material is ground and polished to thin it which makes the stack now have j layers. Then appropriate processes are applied to form vias through the thinned layer and metallization to form the required electrical connection, usually in the forms of a bus, to allow communication and power to be distributed to the j-th layer. With this technique the individual layers are generally 30 to 50 μm in thickness and the via and metallization processes are generally difficult and problematic.

Accordingly a need exists for structures, materials and methods for transposed splitting of ion cut materials. These needs and others are met within the present invention, which overcomes the deficiencies of previously developed ion cutting methods.

### BRIEF SUMMARY OF THE INVENTION

The present invention pertains to a novel structure, material, and process for fabrication thereof, that can be used in the processing of nanodevices containing circuitry as well as other structures. Using the structures, materials and ion cut transposed split methods of the present invention, the layers of silicon remaining after the split are on the order of 1 μm or less, and standard via metallization technology used in current back end integrated circuit methods and structures can be employed.

In general terms, the invention comprises a multilayered structure and material, which will be referred to herein as “material X”. In one embodiment, material X comprises a device layer and a substrate layer. The substrate layer is specifically adapted for the diffusion and collection of hydrogen. Further, the invention describes fabrication methods particularly well suited for diffusing hydrogen within substrates in preparation for splitting of the ion cut material.

The device layer comprises a material, such as single-crystal silicon, having at least a portion that has been optimized for making the device(s) of interest, such as nanostructures.

The substrate layer preferably comprises an insulator layer and a diffusion layer. The diffusion layer has a collection region adjacent the insulator layer.

The insulator layer is optimized to facilitate performing device fabrication steps; in particular the material and its thickness are chosen to provide a high degree of electrical and especially thermal insulation between the diffusion layer and the device layer when material X is used for device fabrication. For example, SiO₂ is a suitable insulator material for a Si device layer since it is an excellent electrical insulator and has thermal conductivity approximately 100 times less than Si. Other oxides and/or combinations of insulating material could be used as well.

The diffusion layer is a material optimized for a high rate of diffusion of hydrogen therethrough, such as moderate to high resistivity single-crystal silicon, especially p-type and other materials known for their high diffusivity of hydrogen. Polysilicon is one such material but, other materials can be used as well. The collection region is preferably a portion of the diffusion layer that is heavily doped with a getter/acceptor material, such as boron, that will capture hydrogen. Alternatively, the collection region could be a portion of the diffusion layer that has been formed into a getter/acceptor region or acts in that manner.

From the foregoing, it will be appreciated that material X has significant differences from conventional structures and materials, such as silicon-over-insulator (SOI) materials, being used in device fabrication.

The invention also comprises a method for fabricating material X. In one embodiment, the process begins with a full thickness wafer having at least a portion that has been optimized for making the device(s) of interest. Next, the wafer is implanted with hydrogen to a depth associated with the thickness to remain after an ion cut. The depth of implantation defines the portion of the wafer that will form the device layer. Prior to the ion cut, the surface of the wafer adjacent the device layer portion is bonded to the substrate layer, preferably to an insulation layer on the surface of that substrate. After bonding to the substrate layer, the wafer is ion cut so as to leave the device layer bonded to the substrate layer.

The substrate layer is formed by creating an insulator layer over the surface of the diffusion layer adjacent the collection region. In one embodiment, the collection region is a heavily doped region formed by implanting a hydrogen getter/acceptor, such a boron, into the diffusion layer. One approach is to implant the hydrogen getter into the diffusion layer at its surface and then grow a layer of oxide over the diffusion layer. This approach is generally less preferred, however, because the oxide tends to “suck out” the hydrogen getter during growth, thereby drawing the getter into the oxide and reducing the efficacy of the collection region. One preferred approach is to form the oxide layer on the diffusion layer by deposition, rather than growth, in which case the oxide will not suck out the hydrogen getter. Another approach is to form the insulator layer first, and then implant the hydrogen getter through the insulator layer to the region just beneath the insulator layer. This approach, however, may be less desirable in cases where the oxide is thick, thereby making implantation of the hydrogen getter through the oxide more difficult.

In another embodiment, the collection region is a portion of the diffusion layer that has been formed into a getter/acceptor region or acts in that manner. For example, damage to a single crystal structure can render a portion of the structure a getter. Additionally, techniques which damage the crystalline structure so as to create voids or other types of collection sites for hydrogen could be employed as well.

Once material X is formed the device layer is processed to form the desired device(s). The device layer is then planarized and bonded to a 3-d stack or handle. The backside of the diffusion layer of the substrate is then thinned, if necessary, and hydrogen is injected and diffused through the backside of the substrate layer and into the collection region. The structure is then ion cut at the collection region.

Standard heating-based diffusion or injection techniques can be used for diffusion of hydrogen through the diffusion layer and into the collection region. The required heating can be carried out in any one of several ways. In one mode, the structure is conventionally heated according to the required time and temperature. In another mode, the backside of the diffusion layer is thinned to reduce the amount of heat required. In another mode, heat is localized spatially and temporally by using pulse heating. In all of these modes, the insulator layer protects the processed device layer as well as the entire stack. In all of these modes, the top of the stack can be attached to a heat sink and held at room temperature while the backside of the diffusion layer is locally heated. However, while the insulator layer serves to protect the processed device layer from heat during diffusion, use of pulse heating further reduces the risk of damage.

Accordingly, an aspect of the invention is a multilayered structure or material for fabrication of a nanodevice, comprising a device layer and a substrate layer adjacent said device layer, the substrate layer comprises a diffusion layer having a region for capture of hydrogen, and wherein said substrate layer comprises an insulator layer between the device layer and the diffusion layer. Preferably, the device layer comprises a material having at least a portion that has been optimized for fabricating said nanodevice, the insulator layer comprises a material that provides a high degree of thermal insulation between the diffusion layer and the device layer during device fabrication, and wherein the diffusion layer comprises a material optimized for a high rate of diffusion of hydrogen therethrough.

Another aspect of the invention is a multilayered structure or material for use in fabrication of a nanodevice, comprising a device layer, an insulator layer adjacent the device layer, and a diffusion layer having a region for capture of hydrogen adjacent said insulator layer. Preferably, the device layer comprises a material having at least a portion that has been optimized for fabricating the nanodevice, the insulator layer comprises a material that provides a high degree of electrical and thermal insulation between the diffusion layer and the device layer, and the diffusion layer comprises a material optimized for a high rate of diffusion of hydrogen therethrough.

Another aspect of the invention is a multilayered structure or material for use in fabrication of a nanodevice, comprising a layer of material for device fabrication, a layer of insulator material, and a layer of material though which hydrogen can diffuse at a high rate and having a region for capture of hydrogen, wherein the layer of insulator material is disposed between the layer of material for device fabrication and the layer of material through which hydrogen can diffuse. Preferably, the device layer comprises a material having at least a portion that has been optimized for fabricating the nanodevice, the insulator layer comprises a material that provides a high degree of electrical and thermal insulation between the diffusion layer and the device layer, and the diffusion layer comprises a material optimized for a high rate of diffusion of hydrogen therethrough.

Another aspect of the invention is a multilayered structure or material for use in fabrication of a nanodevice, comprising a layer of material for device fabrication having at least a portion that has been optimized for fabricating said nanodevice, a layer of material through which hydrogen can diffuse at a high rate and having a region for capture of hydrogen, and a layer of insulator material that provides a high degree of electrical and thermal insulation between the diffusion layer and the device layer during device fabrication, wherein the insulator layer is disposed between the device layer and the diffusion layer.

Another aspect of the invention is a method for fabricating a multilayered structure or material for use in making a nanodevice, comprising providing a wafer having at least a portion that has been optimized for making the nanodevice, implanting the wafer with hydrogen to a depth associated with a thickness to remain after an ion cut, and bonding the wafer to a substrate layer, where the substrate layer comprises a diffusion layer having a region for collection of hydrogen and an insulator layer bonded to the diffusion layer. The wafer is then ion cut so as to leave a device layer bonded to the substrate layer. In one mode, the substrate layer is formed by bonding the insulator layer to a surface of the diffusion layer adjacent a preformed hydrogen collection region. In another mode, the substrate layer is formed by bonding the insulator layer to a surface of the diffusion layer and forming a hydrogen collection region in the diffusion layer beneath the insulator layer.

While the term “wafer” is used herein, the term should be interpreted to encompass a wafer, chip or any portion of a wafer or chip.

Another aspect of the invention is a method for fabricating a multilayered structure or material for use in making a nanodevice, comprising providing a wafer having at least a portion that has been optimized for making the nanodevice, implanting the wafer with hydrogen to a depth associated with a thickness to remain after an ion cut, bonding the wafer to a substrate layer that comprises a diffusion layer having a region for collection of hydrogen bonded to an insulator layer, and ion cutting the wafer so as to leave a device layer bonded to the substrate layer. In one mode, the substrate layer is formed by bonding the insulator layer to a surface of the diffusion layer adjacent a preformed hydrogen collection region. In another mode, the substrate layer is formed by bonding the insulator layer to a surface of the diffusion layer and forming a hydrogen collection region in the diffusion layer beneath the insulator layer.

Another aspect of the invention is a method of fabricating a multilayered structure or material for use in making a nanodevice, comprising providing a wafer having at least a portion that has been optimized for making the nanodevice, implanting the wafer with hydrogen to a depth associated with a thickness to remain after an ion cut, creating hydrogen getters in a diffusion layer to form a collection region, bonding the diffusion layer to an insulator layer, bonding the insulator layer to the wafer, and ion cutting said wafer so as to leave a device layer bonded to the substrate layer.

Another aspect of the invention is a method of fabricating a multilayered structure or material for use in making a nanodevice, comprising providing a wafer having at least a portion that has been optimized for making the nanodevice, implanting the wafer with hydrogen to a depth associated with a thickness to remain after an ion cut, bonding a diffusion layer to an insulator layer, creating hydrogen getters within the diffusion layer to form a collection region, bonding the insulator layer to said wafer, and ion cutting said wafer so as to leave a device layer bonded to the substrate layer.

Another aspect of the invention is a method of fabricating a nanodevice, comprising providing a wafer having at least a portion that has been optimized for making the nanodevice, implanting the wafer with hydrogen to a depth associated with a thickness to remain after an ion cut, forming a diffusion layer having a hydrogen collection region, bonding the diffusion layer to an insulator layer, bonding the insulator layer to said wafer, ion cutting the wafer so as to leave a device layer bonded to the substrate layer, planarizing the device layer, bonding said device layer to a 3-d stack or handle, injecting and diffusing hydrogen into the collection, and ion cutting said diffusion layer at said collection region.

A still further aspect of the invention is a method of fabricating a nanodevice, comprising providing a wafer having at least a portion that has been optimized for making the nanodevice, implanting the wafer with hydrogen to a depth associated with a thickness to remain after an ion cut, bonding a diffusion layer to an insulator layer, creating hydrogen getters within the diffusion layer to form a heavily doped region, bonding the insulator layer to the wafer, ion cutting the wafer so as to leave a device layer bonded to the substrate layer, planarizing the device layer, bonding the device layer to a 3-d stack or handle, diffusing hydrogen into the heavily doped region, and ion cutting said diffusion layer at the heavily doped region.

Further aspects of the invention will be brought out in the following portions of the specification, wherein the detailed description is for the purpose of fully disclosing preferred embodiments of the invention without placing limitations thereon.

### BRIEF DESCRIPTION OF THE SEVERAL VIEWS OF THE DRAWING(S)

The invention will be more fully understood by reference to the following drawings which are for illustrative purposes only:

FIG. 1 is a plot of boron distribution when forming an acceptor plane for ion cutting with a transposed split, showing forward skew of implanted boron.

FIG. 2 is a cross-section of a material containing a device layer and surface layer of insulation positioned with a lower first surface positioned for joining to a high diffusion rate substrate according to an embodiment of the present invention.

FIG. 3 is a cross-section of the multilayer material according to an embodiment of the present invention, showing a weakened cutting plane defining the device layer being ion split cut from the material.

FIG. 4 is a cross-section of the device layer with buried insulation layer attached to a substrate configured for backside hydrogen diffusion according to an aspect of the present invention, showing what is referred to herein as a material X that may be utilized in fabricating circuits, such as for being transferred to a target material or stack.

FIG. 5 is a cross-section of material X of FIG. 4, shown after circuit processing within the device layer.

FIG. 6 is a cross-section of a material X subsequent to the device fabrication processes of FIG. 5, shown after bonding to a target material.

FIG. 7 is a cross-section of the joined material X and target material of FIG. 6, shown after optional thinning of the diffusion layer followed by the implantation of a cutting plane according to an aspect of the present invention.

FIG. 8 is a cross-section of target joined material X and target material of FIG. 7, shown after ion split cutting according to an aspect of the present invention to remove the substrate material (including insulator material) while leaving the device layer.

FIG. 9 is a cross-section of a compound substrate being formed according to an aspect of the present invention, showing a hydrogen getter surface layer coupled to a diffusion layer.

FIG. 10 is a cross-section of the compound substrate of FIG. 9, shown after optional forming of an insulation layer over the collector surface layer.

FIG. 11 is a cross-section of the compound substrate of FIG. 10, shown after optionally incorporating hydrogen injection layer on the opposing surface of the substrate.

FIG. 12 is a cross-section of a joined stack of processed device j-1) layers to which another processed device layer is to be transferred according to an aspect of the invention.

FIG. 13 is a cross-section of a material X having a thicker insulator layer according to an aspect of the present invention, shown with a device layer within which devices for the j-th stack element are to be fabricated.

FIG. 14 is a cross-section of the stack of FIG. 12 bonded to the j-th layer device layer of material X after processing, according to another aspect of the invention.

FIG. 15 is a cross-section of the stack bonded to the device layer and compound substrate of FIG. 14, shown coupled in a configuration for applying heat to the substrate to enhance hydrogen diffusion, while retaining processed device layers in the stack on an opposing surface at a reduced temperature according to an aspect of the present invention.

FIG. 16 is a cross-section of an underlying diffusion layer and a getter/acceptor layer toward the surface of a substrate which has been bonded to a device layer into which nanodevices may be fabricated, according to an aspect of the invention.

FIG. 17 is a cross-section of the device layer joined to the substrate of FIG. 16, shown with an optional dielectric layer between the getter/acceptor layer and device layer according to an aspect of the invention.

FIG. 18 is a plot of hydrogen diffusivity as a function of 1000/temperature (inverse temperature) as reported from different sources.

FIG. 19 is a plot of hydrogen diffusivity providing a detailed view of the high temperature portion of the plot.

FIG. 20 is an Atomic Force Micrograph of a substrate surface injected with hydrogen, showing bubbles which arise in response to hydrogen diffusing to subsurface activated boron, according to an aspect of the present invention.

FIG. 21 is an Atomic Force Micrograph of a substrate surface having activated subsurface boron, wherein hydrogen has not been injected into the substrate and no bubble formation is seen.

FIG. 22 is an optical micrograph showing bubbles on the surface of sample substrates injected with hydrogen at 1×10¹⁶/cm².

FIG. 23 is an optical micrograph of the bubbled surface of sample substrates injected with hydrogen at 5×10¹⁵/cm².

FIG. 24 is an Atomic Force Micrograph of the surface of a hydrogen injected and diffused sample substrate, showing no bubbling in response to a boron dose of 1×10¹⁵ per cm².

FIG. 25 is an Atomic Force Micrograph of the surface of a hydrogen injected and diffused sample substrate, showing surface disruptions beginning to appear in response to a boron dose of 2×10¹⁵ per cm².

FIG. 26 is an Atomic Force Micrograph of the surface of a hydrogen injected and diffused sample substrate, showing small bubbles are appearing across the entire surface in response to a boron dose of 5×10¹⁵ per cm².

FIG. 27 is an Atomic Force Micrograph of the surface of a hydrogen injected and diffused sample substrate, showing full bubble development in response to a boron dose of 1×10¹⁶ per cm².

### DETAILED DESCRIPTION OF THE INVENTION

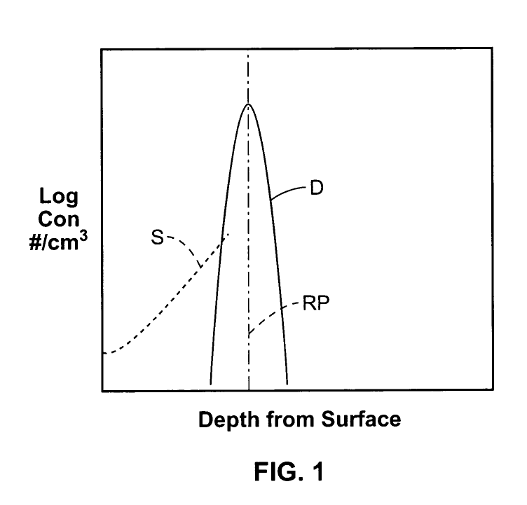

Referring more specifically to the drawings, for illustrative purposes the present invention is embodied in the apparatus generally shown in FIG. 1 through FIG. 27. It will be appreciated that the apparatus may vary as to configuration and as to details of the parts, and that the method may vary as to the specific steps and sequence, without departing from the basic concepts as disclosed herein.

Transposed split methods operate by injecting atoms, such as hydrogen, into a substrate and then diffusing those atoms to a trapping layer (i.e. boron), thereby forming a weakened region, also referred to as a cutting plane, although the shape of the cut need not be strictly planar. The injected atoms will be generally described hereafter as hydrogen although other elements may be alternatively or additionally utilized. The transposed split process relies upon the ability to control the injection and diffusion of these hydrogen atoms. The present invention describes structures, materials and methods for fabricating nanostructures and devices, in particular those containing electronic circuits, which overcome some drawbacks and limitations previously associated with the transposed split method.

During the transposed split process, a hydrogen getter is typically implanted to form a hydrogen collection layer of a desired shape, typically planar, at a desired depth. However, the hydrogen distribution is not Gaussian and a forward (toward the surface) skew arises with regard to the hydrogen getter concentration that can interfere with the fabrication of nanodevices. The hydrogen getter typically comprises an acceptor, and may also be generally referred to as an acceptor layer or plane.

FIG. 1 is a graphical representation of forward skew of an implanted getter/acceptor distribution, such as of boron atoms, when forming a getter/acceptor plane for ion cutting with a transposed split. Depth of atom penetration is shown by Gaussian curve D, with forward skew being represented by dashed line S. The dashed line RP in the figure is a projected range of the first order Gaussian estimate of implanted ion distribution, hereinafter referred to as RP. The shape of the back portion of the Gaussian curve remains generally the same with or without forward skew. The idealized distribution of implanted ions would preferably follow a Gaussian curve centered about RP. However, when implanting lighter ions such as boron within a silicon substrate material, a considerable skew S in the distribution arises toward the surface. The material split arising during the transposed split method occurs substantially centered about RP, wherein the circuitry or nanostructures fabricated in the surface above depth RP is separated or expunged. However, in response to a forward skew, a boron doping level can arise in the surface regions which can interfere with the formation and/or the operation of the nanostructure. It should be appreciated that nanostructures described herein include but are not limited to nanodevices containing circuitry as well as to those containing optics, machines, and combinations thereof. The techniques being particularly well-suited for use with structures that are electrically active.

The problems that arise from having a shallow skewed getter/acceptor distribution can be eliminated according to the invention by forming a substrate having an insulator layer and a diffusion layer, where the diffusion layer has a hydrogen collection region beneath the insulator layer. The insulator layer is subsequently bonded to a structure or material having a device layer that is adapted for being expunged from that structure or material. After the device layer is expunged, the device layer can processed using conventional techniques. Hydrogen is then be injected into from the diffusion layer at the rear of the substrate, which may be optionally thinned beforehand. The hydrogen then diffuses into the collection region, thereby creating an area where the device layer to be expunged from the diffusion layer.

By way of example, the collection region may be a region that is heavily doped with a hydrogen getter, or a region that has otherwise been formed into a getter/acceptor region or acts in that manner. For example, damage to a single crystal structure can render a portion of a structure a getter. Additionally, techniques which damage the crystalline structure so as to create voids or other types of collection sites for hydrogen could be employed.

Where the collection region is a region heavily doped with hydrogen getters, the preferred getter elements for use with silicon are boron or gallium. It will be appreciated, however, that other getters can be utilized depending on the application and materials in use as is known to those in the in the art. For example, while boron and gallium are particularly well-suited for use with silicon substrate materials, but other elements could be used with other substrates. Again, it should be noted that damage sites within the crystalline structure may also act as either donor or acceptor locations.

With further regard to the collection region comprising a heavily doped region, note that implanted ions, such as boron or gallium, must be electrically activated after implantation before they can function as an acceptor. Upon implantation, the ions are not normally located in electrically active sites in the crystal, or the material may still be fully or partially in an amorphous form. Therefore, an activation process is performed, for example according to one or more heating profiles generally referred to as thermal annealing, such as what is commonly referred to as rapid thermal annealing (RTA).

The collection region in the diffusion layer can be formed in the manner described above or in any convenient manner, such as by epitaxial growth, ion implantation, diffusion, damage techniques, other known mechanisms and combinations thereof.

With regard to the substrate layer, it should be appreciated that electronic or other nanostructures are not to be fabricated within this material and, therefore, the manufacturer has substantial latitude with regard to selecting materials for the substrate layer. However, to facilitate backside injection and diffusion of hydrogen, the diffusion layer should comprise a material having a diffusion rate that is optimized for high diffusivity of hydrogen. By way of example, very high diffusion rates are exhibited by forms of polysilicon material, which can be up to about two orders of magnitude higher than single-crystalline material because of grain boundary effects. Other materials, such as high resistivity p-type silicon, provide high diffusion rates for hydrogen and some of these materials may be preferred with regard to their compatibility with aspects of the fabrication process. The selection of high diffusion rate materials typically entails a tradeoff between diffusion rate and other factors which effect compatibility with the desired device processes within which the ion splitting is being utilized.

The insulator layer, or more particularly the insulator layer and diffusion layer, is then bonded to a device layer from another material having at least a surface layer which is suitable for fabricating nanodevices (or likewise microdevices), optical devices, electromechanical devices, mechanical devices and especially electronic devices or combinations thereof. The device layer of the material is defined by a layer of hydrogen or equivalent substance suitably implanted beneath the device layer to create a weakened plane suitable for performing an ion cut (split).

It should be appreciated that the material containing the device layer may comprise any material which is suitable for fabricating the desired forms of nanostructures which can be cut according to an ion cutting process. In silicon device technology the material containing the device layer would generally comprise single-crystalline silicon, or other materials such as SiGe, strained silicon and may or may not include a thin layer of insulator, such as silicon dioxide (SiO₂) and or silicon nitride (SiN₄) or other insulator which is generally rendered hydrophilic. It should be appreciated that insulators for use within the present invention, although typically referring to silicon dioxide or other silicon oxide, may be formed from other oxides formed on the substrate surface, or alternatively insulation formed from any convenient surface processing or surface layering mechanism. A preferred method of bonding comprises direct fusion bonding, at low to high temperatures, to arrive at a material having a suitable device layer coupled to a substrate having a getter/acceptor region and diffusion layer to facilitate ion split cutting.

The device layer and/or the substrate containing the diffusion layer may also be implemented for non-silicon based materials such as GaAs, InP, and so forth. The material selection for the device layer and substrate material including the dopants of the getter region, formation of insulators, injection layers and so forth can be readily ascertained in view of the teachings herein for a given device technology by one of ordinary skill in the art.

To summarize, the invention comprises a multilayered structure and material, which will be referred to herein as “material X”. In general terms, material X comprises a device layer and a substrate layer. The device layer comprises a material having at least a portion that has been optimized for making the device(s) of interest. The substrate layer comprises an insulator layer and a diffusion layer. The diffusion layer has a collection region adjacent the insulator layer.

The insulator layer is optimized to facilitate performing device fabrication steps; in particular the material and its thickness are chosen to provide a high degree of electrical and especially thermal insulation between the diffusion layer and the device layer when material X is used for device fabrication. For example, SiO₂ is a suitable insulator material for a Si device layer since it is an excellent electrical insulator and has thermal conductivity approximately 100 times less than Si. Other oxides and/or combinations of insulating material could be used as well.

The diffusion layer is a material optimized for a high rate of diffusion of hydrogen therethrough, such as moderate to high resistivity single-crystal silicon, especially p-type and other materials known for their high diffusivity of hydrogen. Polysilicon is one such material but, other materials can be used as well. The collection region is a preferably a portion of the diffusion layer that is heavily doped with a getter/acceptor material, such as boron, that will capture hydrogen. Alternatively, the collection region could be a portion of the diffusion layer that has been formed into a getter/acceptor region or acts in that manner.

Material X can be fabricated in several ways. One approach is to start with a full thickness wafer having at least a portion that has been optimized for making the device(s) of interest. The wafer is then implanted with hydrogen to a depth associated with the thickness to remain after an ion cut. The depth of implantation defines the portion of the wafer that will form the device layer. Prior to the ion cut, the surface of the wafer adjacent the device layer portion is bonded to the substrate layer. After bonding to the substrate layer, the wafer is ion cut so as to leave the device layer bonded to the substrate layer.

The substrate layer is formed by bonding the insulator layer to the surface of the diffusion layer adjacent the collection region. For example, the collection region can be a heavily doped region formed by implanting a hydrogen getter/acceptor into the diffusion layer. One approach is to implant the hydrogen getter into the diffusion layer at its surface and then the grow a layer of oxide over the diffusion layer. This approach, however, is less preferred because the oxide tends to “suck out” the hydrogen getter during growth and thereby drawing the getter into the oxide and reducing the efficacy of the collection region. A preferred approach is to form the oxide layer on the diffusion layer by deposition, rather than growth, in which case the oxide will not suck out the hydrogen getter. Another approach is to form the insulator layer first, and then implant the hydrogen getter through the insulator layer to the region just beneath the insulator layer. This approach, however, may be less desirable in cases where the oxide is thick, thereby generally making implantation of the hydrogen getter through the oxide more difficult.

Alternatively, the collection region is a portion of the diffusion layer that has been formed into a getter/acceptor region or acts in that manner. For example, damage to a single crystal structure can render a portion of the structure a getter. Additionally, techniques which damage the crystalline structure so as to create voids or other types of collection sites for hydrogen could be employed as well.

In use, the device layer is processed to form the desired device(s). The device layer is then planarized and bonded to a 3-d stack or handle. The backside of the diffusion layer is then thinned, if necessary, and hydrogen is injected and diffused through the backside and into the collection region. The structure is then ion cut at the collection region.

Note also that, generally, the insulator layer which is placed between the active thin layer and the substrate layer can be formed on either the substrate or the active layer to be thinned, or on both. The preferred method of forming the insulator layer is by oxidation, such as in the case of forming thermal SiO₂. Alternatively, the insulation may be formed by any convenient means, such as using deposition techniques well known in the art, or other methods. However, in cases that may be applicable to pulse heating, it may be desired to have the insulator 10 to 20 μm in thickness to achieve the thermal isolation needed to prevent overheating the stack. In such cases more elaborate methods of forming the insulator may be more desirable. As an example a thick layer of insulator would be deposited and planarized where the getter structure was first formed on the substrate surface before insulator deposition and planarization. Or an even more elaborate technique could be employed where a thick insulator would be deposited onto insulator bearing substrate with a getter layer at the surface on a hydrogen diffusion optimized substrate. The thick insulator surface of this structure would then be bonded to the material X substrate with a hydrogen getter region on it at which point the thick insulator layer would be expunged to the material X substrate by injecting and diffusing hydrogen into the insulator bearing substrate. This latter structure and process would allow an arbitrarily thickness insulator process to be incorporated into material X without compromising any of the regions of material X. At the end of the process when the substrate of material X is removed, the thick insulator would be etched from the bottom of the stack.

While such an elaborate methods may be feasible and even practical, simple calculations show that insulator layers of the order of 20 μm in thickness are sufficient to prevent the stack from rising above ˜165 degrees C. with the backside of the substrate held at 1000 degrees C. A more modest layer of 5 μm would allow a worst case stack temperature of ˜265 degree C. with 800 degree C. held at the backside of the substrate. The presently contemplated best mode for producing the 5 μm insulator would be the simpler deposition and planarization approach.

Note also that thin layers of materials produced by the instant material X technology introduce a potential heat dissipation problem. This problem is addressed in this technology by interspersing heat dissipation layers into the stack as it is being built to appropriately dissipate heat as required. The heat dissipation layers can take the form of passive layers of high thermal conduction materials such as Cu or diamond appropriately insulated or various MEMS nano refrigeration systems as are well know in the art. Interspersed RF shield layers may also be placed in the stack at appropriate places to avoid electro magnetic interference between layers of the stack.

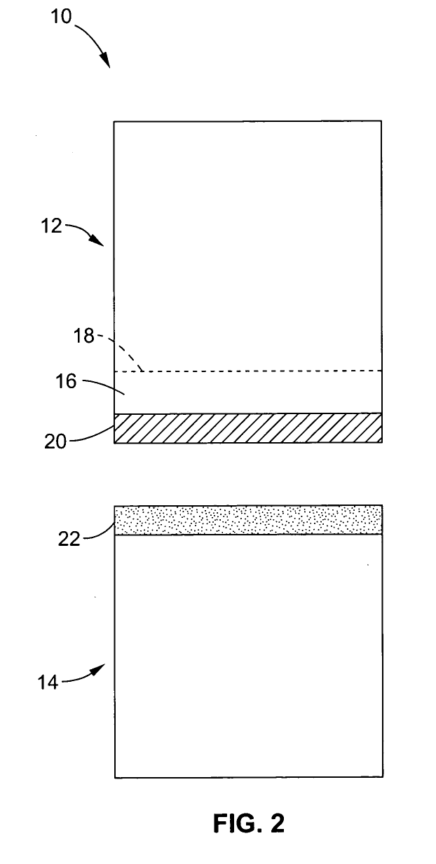

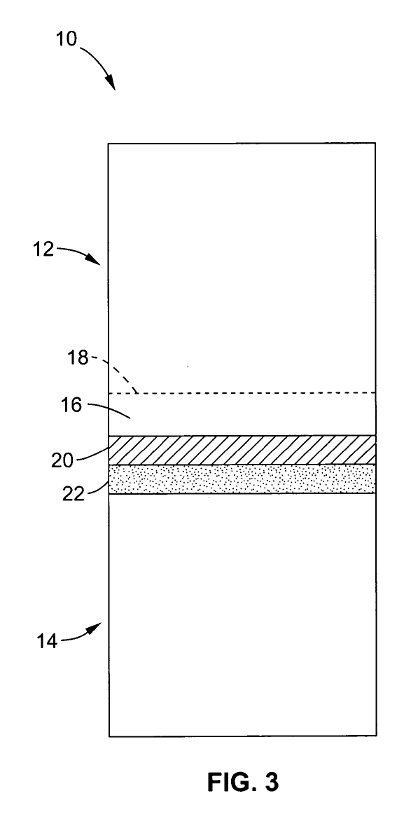

Referring now more particularly to FIG. 2 through FIG. 8, those figures depict bonding the described substrate layer (e.g., insulator layer and diffusion layer with a hydrogen getter/acceptor region) to a material from which a device layer is expunged and within which nanodevices are fabricated, wherein the device layer is then shown being transferred to a target material. It should be appreciated that the processed device layer may be transferred to any desired target material, such as forming a layer within a stack of processed device layers which are preferably electrically interconnected. FIG. 2 depicts materials 10 with a upper material 12 whose underside first surface is positioned for bonding over a substrate 14. A device layer 16 of upper material 12 is defined between the surface of the material and cutting plane 18, which was weakened such as by hydrogen implantation in preparation for splitting. FIG. 3 depicts a multilayered material 10 after joining upper material 12 to a first surface of substrate 14, prior to performing an ion cut process to expunge device layer 16.

The upper material containing device layer 16 is exemplified as a single-crystal silicon layer 12, for example with at least the bonded interface optimized for CMOS or other device technology to be fabricated. The single-crystalline silicon shown can be optimized for being doped to suit a particular nanodevice application or derivatives of the same, such as strained Si or SiGe circuits.

An insulator layer 20 is preferably formed under device layer 16 of upper material 12. Preferably, insulator layer 20 for a silicon substrate comprises an insulator such as silicon dioxide (SiO₂), silicon nitride (Si₃N₄) or other insulator or combination of insulators, to otherwise form or provide a suitable layer for bonding with substrate 14. An ion cutting plane 18 formed at a predetermined depth allows ion splitting of device layer 16 from material 12. The material of substrate 14 is preferably a material optimized for hydrogen diffusion so as to provide a sufficient level of hydrogen diffusion to support diffusing hydrogen through the material which has been injected from the backside. A first surface region 22 of substrate 14 is configured with sufficient hydrogen getter to collect hydrogen diffused from the backside. Preferably the hydrogen getter comprises a heavily-doped region, such as doped with boron, toward the surface of substrate 14. In one embodiment, the region is heavily doped with boron at a preferred dose equal to or exceeding approximately 5×10¹⁵/cm².

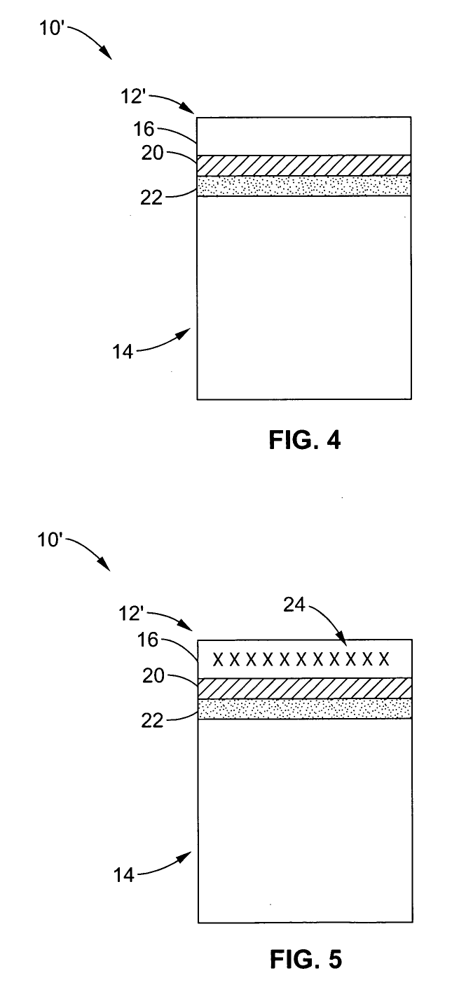

FIG. 4 shows material 10′ which results after the ion splitting process, which has removed all of material 12 except device layer 16 which is attached to substrate 14. Device layer 16 remains as a remnant of material 12 and is referenced in the figure as material 12′. After ion cutting, the surface of device layer 16 is preferably planarized in preparation for device fabrication processes therein.

It should be appreciated that multilayer material 10′ depicted in the figure represents a device substrate material having a device layer, such as silicon, over an insulator. The novel multilayer material 10′ which is referred to herein generally as “material X” provides a device layer over an insulator layer upon which a number of device technologies can be fabricated, along with substrate properties particularly well-suited for ion split cutting. Buried insulator structures, like conventional silicon over insulator (SOI), provide a number of advantages when fabricating CMOS and many other semiconductor technologies. This novel material X has an insulator layer beneath the device layer, and diffusion layer with a hydrogen getter/acceptor region beneath the device layer wherein hydrogen can be injected and diffused from the backside of the material and into the getter/acceptor region for subsequent expunging of device layer 16.

FIG. 5 depicts nanodevices 24 (illustrated simply as a set of X's) fabricated in device layer 16 of multilayer material X 10′, such as to form CMOS or other nanostructures on substrate assembly 10′. Because of the novel properties of material X the nanodevices of device layer 16, along with optional insulator layer 20, can be readily transferred to a target material, such as to be stacked with other device layers.

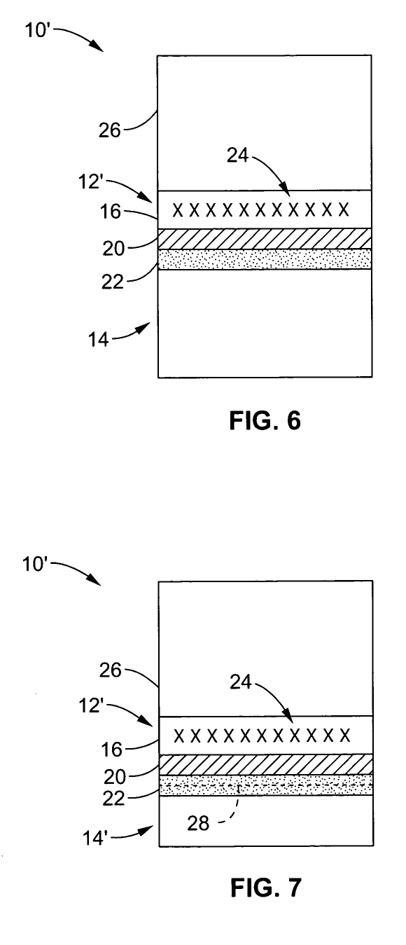

FIG. 6 depicts a target material 26 bonded to the surface of planarized device layer 16 containing nanodevices 24.

FIG. 7 depicts hydrogen having been introduced into the backside of material X 10′ and diffused to the getter/acceptor region (or layer) 22 creating a weakened plane 28 in preparation for ion splitting. Material X is shown having been optionally thinned to facilitate diffusion. The need for thinning depends on the diffusion characteristics of the material selected for substrate 14, or the diffusion layer therein. It is generally preferable that substrate 14 be chosen of a material with a sufficiently high diffusion rate so that thinning is unnecessary for obtaining sufficient hydrogen diffusion through the backside of the substrate material. Injection into the backside of material X may be performed by any convenient process, such as by an implanting process, preferably it is performed in a manner which does not significantly impact diffusion mobility.

The hydrogen injection process may be performed by injecting a stream of atomic hydrogen into the backside of the material. Preferably the injection is performed with H₁. Injecting H₂ or H₂⁺ would typically be less effective at creating a weakened plane due to the difficulty with injecting it into the material and diffusing (or drifting) the atoms to the plane to be weakened.

It should be appreciated that the injection process is preferably performed at a sufficiently low energy so as to limit the material damage, to prevent any unwanted trap formation at the point of injection, and to allow for subsequent diffusion of atoms to form a weakened plane. In the present embodiment, the hydrogen atoms are non energetic at a room temperature of approximately 20 degrees C.

Studs for use in forming electrical vias may be optionally created on select portions of the insulation layer or the getter/acceptor region either before or after thinning. It is preferred that studs be inserted externally from the top of the processed layer 16 into the insulating layer 20 during the processing step.

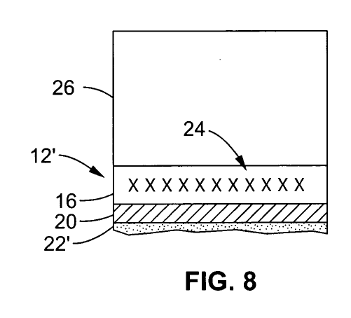

FIG. 8 depicts insulated device layer 16 having been transferred from the surface of material X to target material 26 after splitting at weakened plane 28, leaving a remnant of getter/acceptor layer 22 depicted as layer 22′. It should be noted that the jagged appearance of the surface after splitting is highly exaggerated to improve visibility. The remaining portion of the getter/acceptor layer 22′ can be removed or thinned, such as by etching as can the insulator layer. Therefore, the thin processed CMOS or other forms of nanodevices fabricated into material X has been transferred from original device material 12 to a target material 26. The process can be repeated to add additional device layers to the target material. It is contemplated that devices fabricated in device layer 16 will be configured for electrical connectivity with the target material, or device stack, and/or with subsequently added device layers, such as within a stack of device layers.

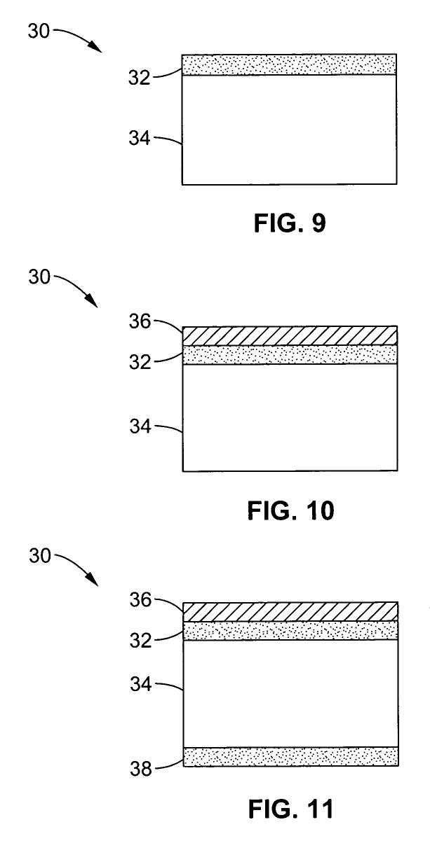

FIG. 9 through FIG. 11 depict substrates that may be utilized according to the invention by bonding to a device layer being expunged from a material. Devices fabricated within the expunged device layer can be subsequently transferred to a target material. FIG. 9 illustrates an example of a compound substrate 30 with a getter/acceptor region 32 in diffusion layer 34. Getter/acceptor layer 32 is adapted for collecting hydrogen, or other atoms used during ion cutting, and is preferably heavily doped with boron, or other forms of getters/acceptors. However, the getter/acceptor region 32 can be adapted for hydrogen collection in other ways as previously discussed. The getter/acceptor layer is preferably adapted to trap hydrogen atoms which have diffused through diffusion layer 34. It is also contemplated that a base of polysilicon may be utilized having a surface layer which has been recrystallized into a layer of single-crystalline material.

It should be appreciated that by utilizing a material with a sufficiently high diffusion rate, the backside of the substrate may not need to be thinned prior to the injection and diffusion of hydrogen in preparation for ion splitting. Elimination of the thinning step speeds processing and can significantly reduce fabrication costs. The compound substrate of FIG. 9 can be utilized for bonding to and expunging a device layer from a material adapted for nanodevice fabrication.

FIG. 10 depicts a modified compound substrate 30 after adding an insulator layer 36 (i.e. SiO₂, SiN₄, and so forth) over the collection region 32 in the diffusion layer. For example, the collection region can be a heavily doped region formed by implanting a hydrogen getter/acceptor into the diffusion layer. One approach is to implant the hydrogen getter into the diffusion layer at its surface and then grow a layer of oxide over the diffusion layer. This approach tends to be less preferable, however, because the oxide tends to “suck out” the hydrogen getter during growth and thereby drawing the getter into the oxide. This can reduce the efficacy of the collection region. One preferred approach is to form the oxide layer on the diffusion layer by deposition, rather than growth, in which case the oxide will not suck out the hydrogen getter. Another approach is to form the insulator layer first, and then implant the hydrogen getter through the insulator layer to the region just beneath the insulator layer. This approach, however, may not be as desirable in cases where the oxide is thick, thereby making implantation of the hydrogen getter through the oxide more difficult.

FIG. 11 illustrates another modification to compound substrate 30 after adding an optional layer 38 configured to optimize the hydrogen injection process. This injection optimization layer 38 may comprise any of a number of known materials, such as hydrated amorphous silicon (Si).

It should be appreciated that compound substrate 30, from FIG. 9-11, or other described and undescribed variants may be utilized in the transposed ion split process for transferring a device layer, or joined to an expunged device layer to form a modified version of material X, having a low resistivity semiconductor surface with buried insulator generally adjacent to a substrate getter/acceptor region of a substrate for collecting hydrogen which has been diffused from the backside of the substrate. The material of the substrate being optimized to support high rates of hydrogen diffusion through the backside.

It is generally preferred that the extent of injection, diffusion, and collection be optimized, insofar as is reasonably practical, in each of the layers beneath the bonding layer. It should also be recognized that other considerations, such as cost, workability issues and so forth may warrant utilizing a material that is “sub-optimal” for the stated purpose of injection, diffusion, or collection. Diffusion can be increased by utilizing high resistivity materials, lightly doped Si, and so forth. The preferred material is p-type silicon doped 10-50 ohm-cm. In this example the rate of diffusion for the structure may be controlled by modulating aspects of any of these three underlying layers. The effectiveness of the collection layer can be increased by heavily doping the material with boron, or other efficient acceptors. Other mechanisms for boosting collection include introducing intentional “defect” structures, such as created in response to injection of Be, Ne, Ar which are stable over the temperatures utilized in fabricating the processed layer.

It should be appreciated that the layers for a described bonding structure may comprise a number of combinations of material, such as Si, derivatives of Si (SiGe, strained silicon, etc.) as discussed earlier, or other materials which may be selected for use with an ion cutting process. The materials selected need not have bondable properties themselves for performing the ion splitting, but they need to be attachable in some manner to an a device layer, such as an insulator layer, that may be utilized for bonding to the substrate material.

The low temperature diffusion calculations in Table 1 clearly illustrate that sufficient hydrogen can be captured to create expunged layers by injecting and diffusing hydrogen from the backside of a full-thickness substrate. However, the times and temperatures involved can place significant demands on metal contact integrity if multiple layers of material are to be stacked. The increased need for extended times and temperatures arises because each successive layer of material multiplies the time-temperature product to which the previously stacked layers are subjected.

The present invention contemplates a number of methods for reducing the time and temperature requirements within a multiple-layer structure. In general, the current layer of a stack being hydrogenated can be thermally isolated from the current active layer and the rest of the stack.

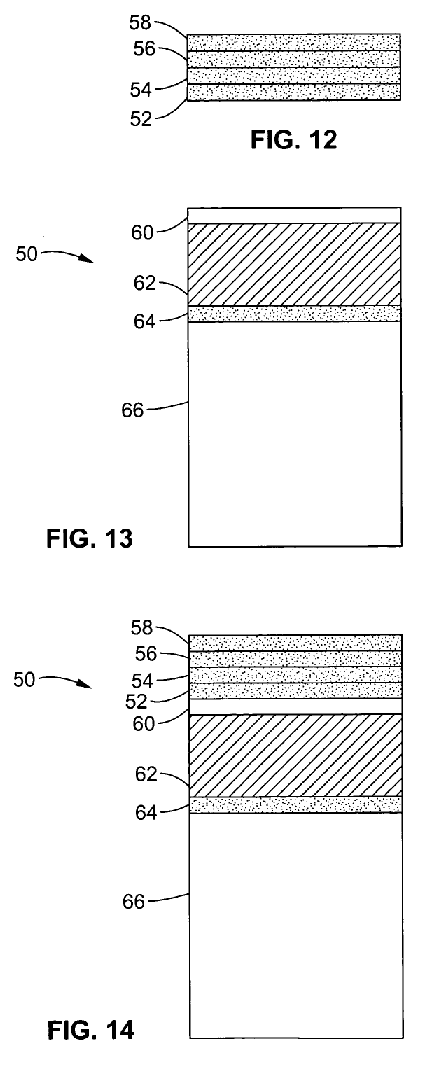

FIG. 12 through FIG. 15 exemplify a transposed split method which can be performed without thinning of the substrate layers during transfer, and which does not subject previously joined device layers to damaging time-temperature exposure. FIG. 12 depicts a stack of j-1 device layers 52, 54, 56, 58 in which each of the j-1 device layers is composed of a thin layer of processed semiconductor covered with a relatively thin layer of insulator preferably imbedded with interconnects. The insulating layers are preferably filled with metallic fill within all areas not needed for insulation, wherein the j-1 layers attain a thermal appearance similar to a slab of silicon of thickness (j-1)x, where x is the thickness of a single layer.

FIG. 13 depicts a form of material X created with a device layer 60 suited to fabricating the j-th layer of nanodevices to be coupled to the j-1 stack of nanodevices according to the present invention. Device layer 60 was bonded to a preferably thick insulator layer 62, a getter/acceptor trap layer 64, and a diffusion layer 66 prior to processing device layer 60 to fabricate nanodevices with appropriate interconnects. Portions of layer 60 not required for insulation are preferably filled with a metallic fill to increase thermal conductivity. Once the j-th device layer is fabricated it can be bonded to the j-1 device layers.

In FIG. 14 processed device layer 60 providing a j-th device layer, still attached to the substrate, has been bonded to the stack of j-1 layers 52 through 58 of FIG. 12. The j stack (including the j device layer bonded to the j-1 layers) can then be transferred to a target material after diffusing sufficient hydrogen into the substrate to form a weakened plane through which the material is split.

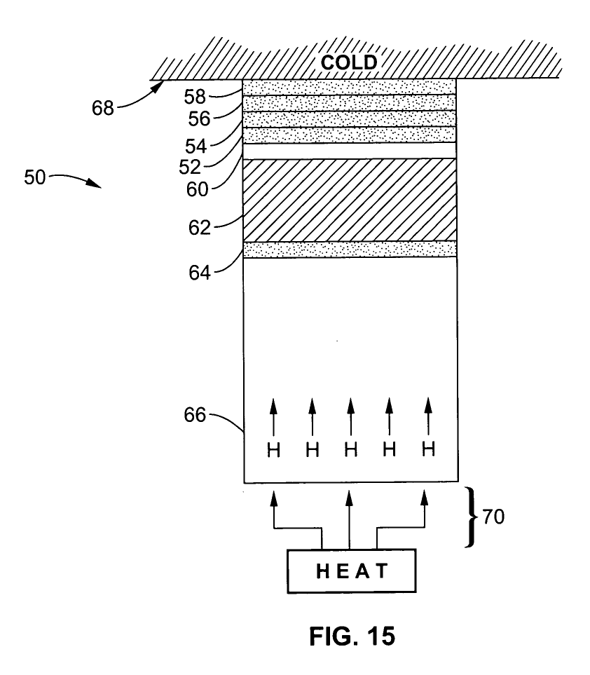

FIG. 15 illustrates a method for increasing the hydrogen diffusion rate for hydrogen injected from the backside of material X and which collects at the hydrogen getter preferably comprising a layer. The substrate is heated from the bottom (backside), containing the diffusion layer (i.e. with a heat lamp, RTA, or other method of heating) while the top of the stack is thermally coupled to a relatively cold surface, such as a large thermal mass and/or heat sink at room temperature. The cool surface, although shown against the top of the j stack, may be thermally coupled to a target material to which the device layer stack is being created. It should also be appreciated that the top of the stack may be cooled at other than room temperatures, and that alternative means for cooling the stack may be utilized within the method without departing from the teachings of the present invention. The relatively thick insulator 62 can be readily designed to allow the j-th hydrogen diffusion and trap layer 60 to be heated to a relatively high temperature to increase the rate of hydrogen diffusion to the trap, while maintaining all j layers at a lower temperature, such as near room temperature.

An important aspect of this design approach is that the relatively thick insulator layer 62 can comprise a material exhibiting low thermal conductivity, such as silicon dioxide (SiO₂). Silicon dioxide has a thermal conductivity approximately one hundred times less than silicon, wherein a few micrometers of silicon dioxide (SiO₂) provides a similar thermal isolation effect as a few hundred micrometers of silicon. This low thermal conductivity substantially enhances the ability of insulator layer 62 to thermally isolate the j-layers of the stack. Consequently, the hydrogen diffusion layer 66 can be heated without significantly heating the j stacked layers, such as pulse heated to as much as 800° C. to over a 1000° C. for the order of a minute to fully hydrogenate the collection layer. These times are supported by the values reflected in the high temperature diffusion calculations of Table 1.

It should be appreciated that if boron does not sufficiently trap hydrogen at high temperatures, such as during pulse heating at about 800 to 1000° C., then as hydrogen is injected into the substrate layer it will be rapidly flooded with a high concentration of hydrogen. As the substrate layer rapidly cools at the end of the pulse heating the boron trap will activate and trap the boron in this trap region.

It is preferred that the pulse heating process rapidly raise the temperature of the diffusion layer within the substrate to facilitate hydrogen diffusion and be followed by quench cooling of the substrate to trap the hydrogen. By way of example, a means for pulse heating the backside of the substrate while injecting hydrogen may be configured by adding an array of heating lamps interspersed with the ion output holes of an ion injection device. During ion injection within a chamber preferably configured with gate valves the heating lamps are activated for a short time (e.g. one minute), the ion source is cut off, and the gate valves to the chamber are closed, cutting off the turbo pump and the plasma to isolate the chamber. The chamber is then flooded with nitrogen, such as through a purge valve, to effect rapid cooling. The process is beneficially performed while maintaining the device stack at room temperature because of the heat sink.

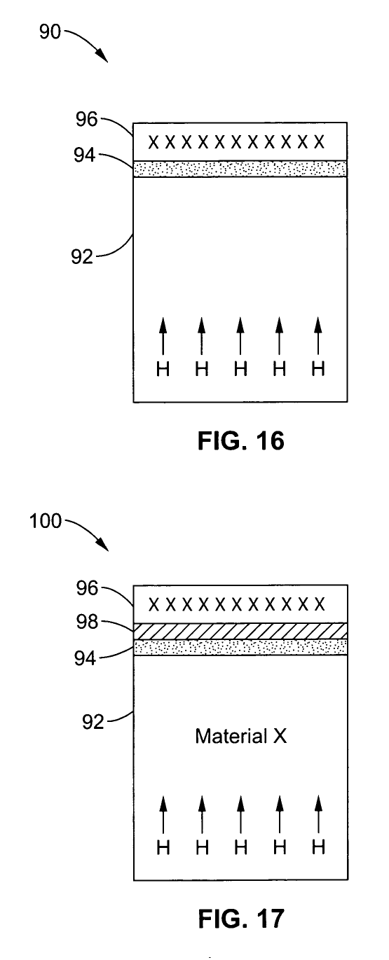

FIG. 16 and FIG. 17 are generalized examples of structures configured for performing the transposed split method using backside injection and diffusion of hydrogen to a hydrogen getter surface, preferably a layer. Numerous benefits can be derived from injecting and diffusing hydrogen into a chip or wafer from the backside and capturing it on a trapping layer created beneath an active layer of a nanodevice. The general case of backside injection is represented by the material 90 of FIG. 16, shown having a diffusion layer 92 over which is formed a hydrogen getter, preferably a layer 94. A processed device layer 96 is bonded to the getter/accepter layer 94, the device layer having been expunged from a material suitable to the device technology being fabricated, planarized, and undergoing circuit fabrication processes to create devices. The figure is shown with injected hydrogen being diffused through diffusion layer 92 toward the hydrogen getter 94 where it will collect and form a weakened plane allowing ion cutting of device layer 96 from the diffusion layer 92.

FIG. 17 illustrates a specific example of backside injection through a material X 100, having diffusion layer 92, getter/acceptor layer 94, insulator layer 98, and device layer 96, which is represented as having already been processed.

It should be appreciated that utilization of the described backside processes depend on the ability to effectively inject and diffuse hydrogen into the substrate material, which is most commonly silicon.

A central challenge overcome within the present invention is that of injecting and diffusing hydrogen over longer distances, from which a host of benefits are derived, such as eliminating or reducing the need for thinning the backside of the substrate and providing thermal isolation of fabricated structure layers as exemplified in FIG. 12 through FIG. 15.

Considerations on the distance through which hydrogen can be practically diffused through a substrate having a diffusion layer according to the present invention are important. For example, it is important to understand whether hydrogen can be diffused through the entire substrate, or whether some thinning will be necessary to facilitate diffusion. Describing the diffusion process of hydrogen through a substrate, in particular silicon, has been actively studied for over a decade with widely varying results.

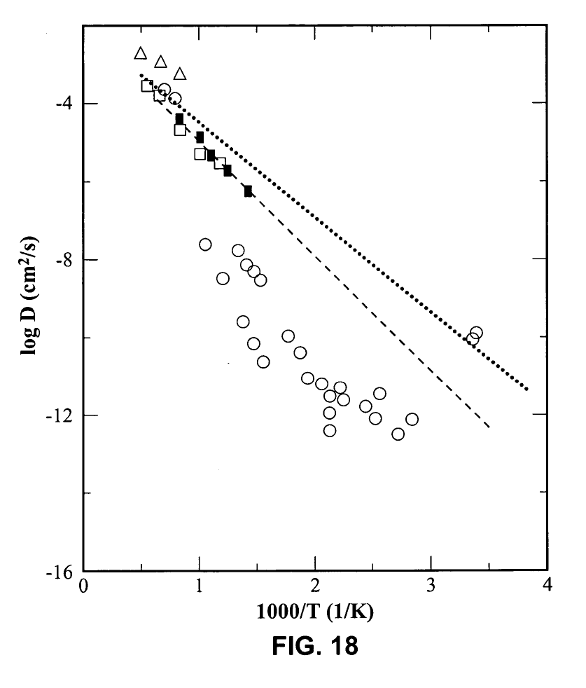

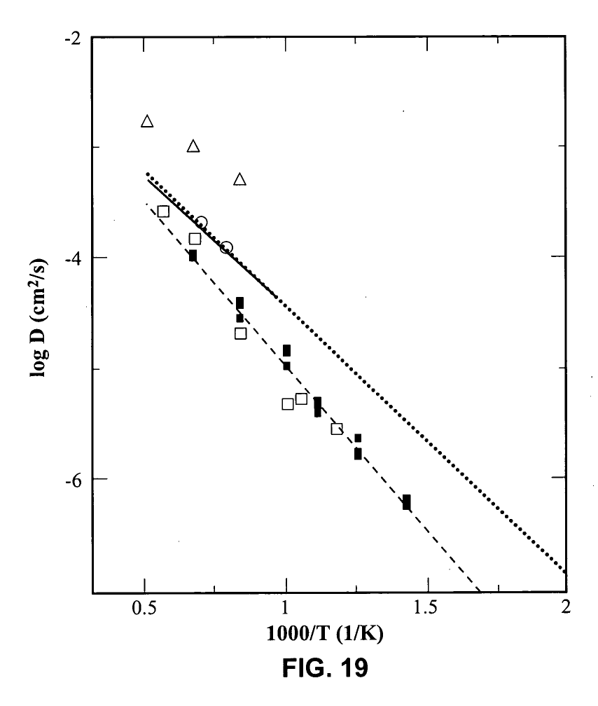

FIG. 18 and FIG. 19 are extracted from the literature to illustrate the varied diffusivities reported for hydrogen diffused in single-crystalline silicon. FIG. 19 is a detailed view of the high-temperature region depicted in FIG. 18. It will be noted that the data collected by Beddard & Lewis is indicated by the blackened squares, and the dashed line is an Arrhenius fit to them. Data from other researchers is also shown in the open circles with corresponding dofted line extrapolation to lower temperatures, and the open triangles. It will be appreciated from this that substantial disagreement exists as to values for hydrogen diffusion.

More recent articles have added to the understanding of the subject (see G. Panzarini and L. Colombo, Phys. Rev. Lett. 73, 1636 (1994); Sabrina Bedard and Laurent J. Lewis, Physical Review B, Volume 61, number 15, 15 April 2000-1; both of which are incorporated herein by reference). The above article by Bedard and Lewis attempts to clarify the situation and proposes an approximation to their tight binding model in the form of a simple Arrhenius relationship where

$$D = {8.910}^{- 3} exp \frac{- 0.58 e V}{kT} .$$

FIG. 19 is extracted from this article and illustrates work over a considerable temperature range including early experimental work and focuses on the more limited temperature range in which the work of Bedard and Lewis is compared with other theoretical work.

To the extent that a simple Arrhenius relationship can be utilized to characterize the diffusion process, Fick's second law

$$\frac{\partial C}{\partial t} = D {∇}^{2} C$$

is applicable with the boundary conditions C₀(0)=K/(α+D/Xₜ) where K is the injected flux density of hydrogen that enters the silicon, α is the rate of flux loss into the vacuum at the surface, and at the location of the boron traps Xₜ the density of hydrogen is zero. With these boundary conditions a numerical solution to the problem must be employed. A program written by Finnis was utilized herein for solving this equation for the present invention under the boundary conditions given. Using this program, solutions to the diffusion problem have been given in Table 1 under a number of different sets of conditions.

Within the values provided by Table 1, three values of D were determined at each temperature and flux condition. The values of D were taken from the Arrhenius relationship given in the Bedard and Lewis article, the high values came directly from the Bedard and Lewis article Arrhenius relation, with the medium values one order of magnitude lower, and the low values two orders of magnitude lower. Two ranges of temperature are generally represented in Table 1. A low temperature range extending in 25° C. increments from 350° C. to 425° C. and a high temperature range related to a pulse heat technique ranging from 900° C. to 1160° C. and materials 500 μm thick at a variety of diffusivities and fluxes. Flux rates of 1×10¹⁶, 1×10¹⁶, 5×10¹⁶ and 1×10¹⁷ cm²/sec were used in the low temperature calculations and 5×10¹⁶ was used in the high temperature cases. A section of the table lists values wherein it is assumed the material is thinned to 100 μm. The times computed are calculated times required to accumulate 3×10¹⁶/cm² of hydrogen, a value Q, at the boron trap sites located near the top of the material as described previously. A column is provided which estimates the time that would be required using a simple steady state solution (Fick's 1st law), in which T_{sec} linear=Q_{req}×X,/(F/β), where Q is the required dose for bubble formation set at 3×10¹⁶/cm², Xₜ is the trap position, F is the flux of hydrogen injected into the silicon and β is related to the surface concentration Co=F/β. The comparison of t, the entire solution to the time dependent equations with the steady state, it can be seen that a transient period is followed by a period where the accumulation proceeds in or near the steady state.

To ascertain if sufficient hydrogen diffusion is occurring, details about void formation in boron implanted silicon injected and diffused with atomic hydrogen have been collected during testing. We have observed that single-crystal (100) silicon placed in a beam of atomic hydrogen for times ranging from 2 minutes to 10 hours at temperatures between 275 and 400° C. produce voids in the form of bubbles when an appropriate dose of subsurface boron has been implanted and activated in this region of the material.

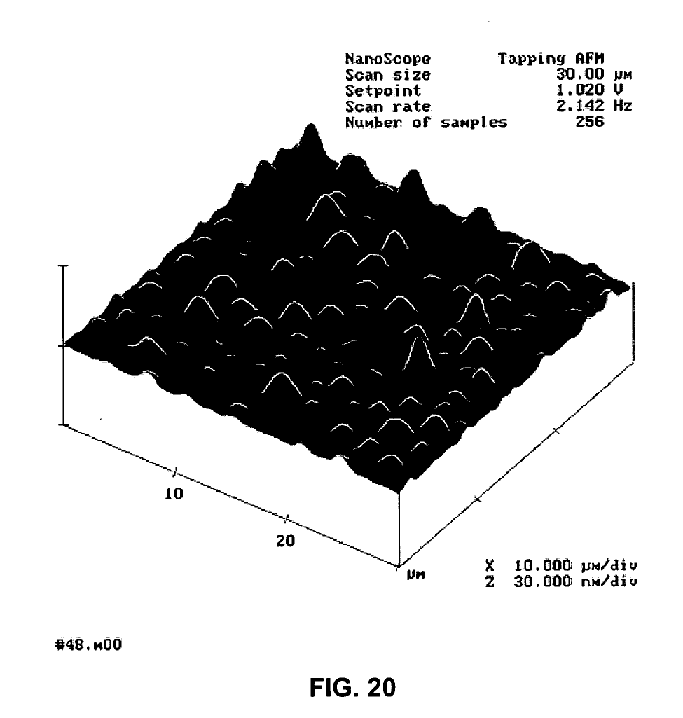

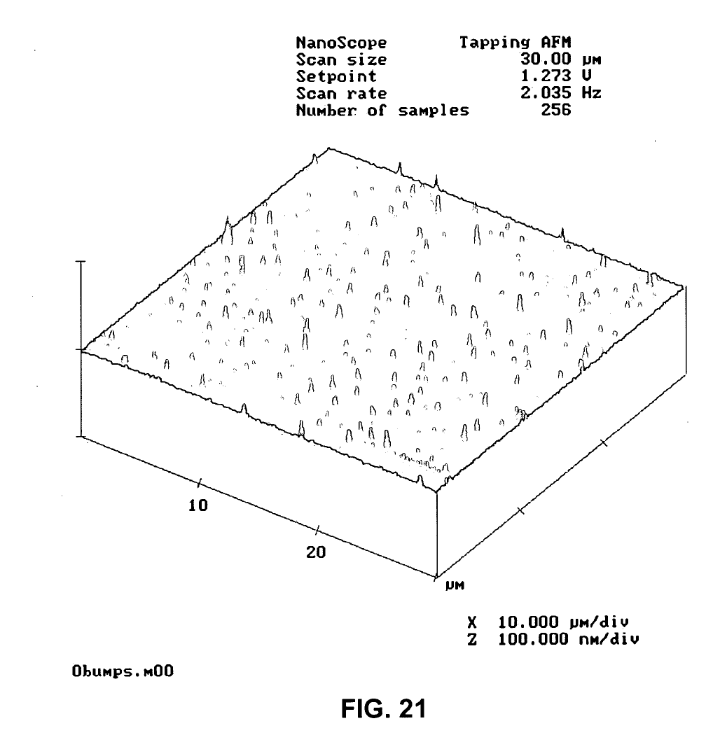

FIG. 20 and FIG. 21 are Atomic Force Micrographs comparing injected and non-injected samples. FIG. 20 is a micrograph of the surface of a sample (sample 11) injected in response to a beam intensity of 1×10¹⁶/cm² under a temperature of 325 for 7 hours. FIG. 21 depicts a sample which has not been subjected to irradiation with hydrogen and no bubbles are evident. Bubbles have also been reported when hydrogen is plasma injected into single-crystal silicon with a subsurface high concentration boron distribution, and voids in the form of bubbles have also been observed when hydrogen is ion implanted into single-crystal silicon. If single-crystal silicon is directly bonded to a handle wafer, the voids manifest themselves as platelets that result in expunged layers of silicon as utilized in the formation of silicon-on-insulator.

Furthermore, when a region of single-crystal silicon has a high hydrogen and boron concentration, the incidence of voids (bubbles or platelets) occurs at lower temperatures and lower hydrogen doses than is observed in the absence of the boron.

Finally, if the boron and hydrogen distributions are spatially displaced from one another, the hydrogen can migrate to the boron distribution and expunge a layer of silicon from a location near the center of the boron distribution (see Robert W. Bower, Louis Lebo and Y. Albert Li, “Transposed Splitting of Silicon Implanted with Spatially Offset Distributions of Hydrogen and Boron”, published II Nuevo Cement December 1997, Vol.19 D, N. 12, pp 1871-1873; and U.S. Pat. No. 6,346,458 B1; both of which are incorporated herein by reference). That work focused on directing a high flux beam of spectrally pure atomic hydrogen onto the surface of boron implanted silicon at a range of temperatures from 275° C. to 400° C. for times ranging from two minutes to ten hours. The atomic hydrogen beam was found to have a spectral purity of H/H2 of greater than 750 to 1. In this example the beam was projected through a pinhole with the sample 15 cm from the hole. The beam striking 6 mm by 12 mm samples in a cos² distribution with a flux of 5×10¹⁵ H atoms/cm²/second. Bubbles were observed to form with boron doses of 5×10¹⁵ and 1×10¹⁶/cm² implanted at 90 and 180 Kev with mean penetration depths of 0.26 cm and 0.5 cm respectively.

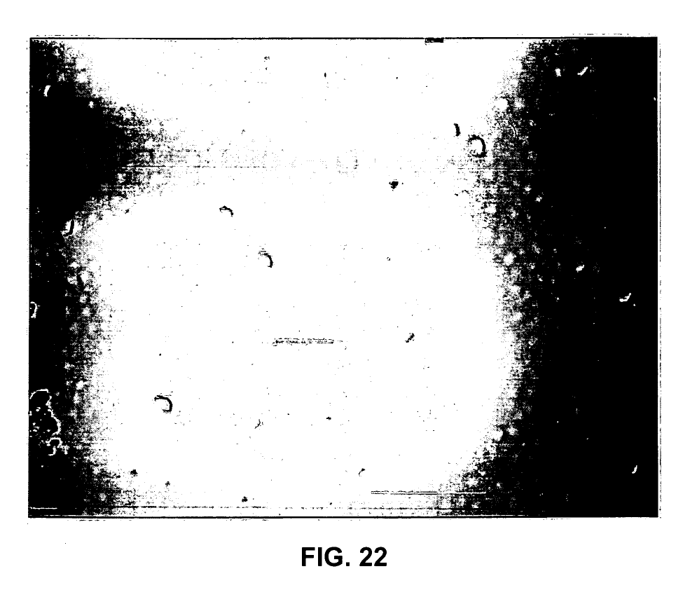

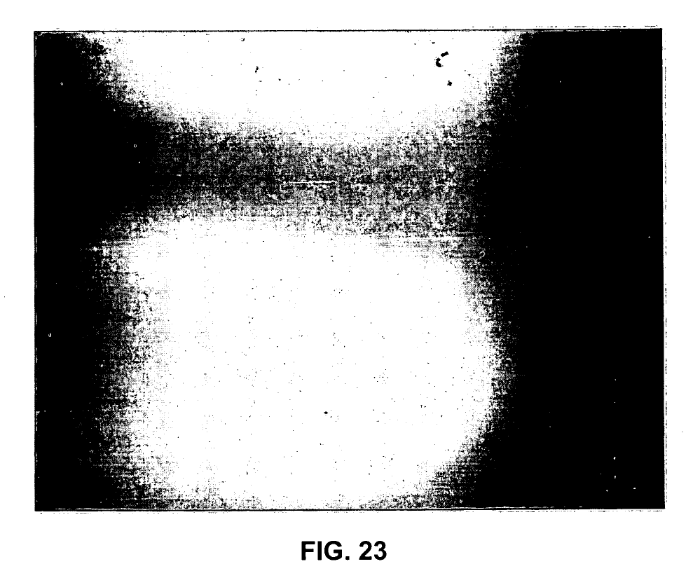

FIG. 22 and FIG. 23 are micrographs of the surface of samples which were injected with hydrogen at 1×10¹⁶/cm² for the sample of FIG. 22, and 5×10¹⁵/cm² for the sample of FIG. 23. From these micrographs bubble densities of 0.5×10⁶/cm² to 1.0×10⁶/cm² were estimated, respectively. Bubbles formed only when the boron had been exposed to a thirty second rapid thermal anneal at 900° C. to anneal implant damage and to activate the boron. Therefore, it appears from the test results that acceptors such as boron and gallium in silicon have the ability to capture between five and ten hydrogen atoms for each boron atom. The boron doses that successfully created bubbles would then trap greater than 3×10¹⁶/cm² hydrogen, a dose that is known from previous investigations to be required to cause bubble formation in single-crystal silicon ion implanted with boron and hydrogen in a localized region.

The boron doses and requirement for a rapid thermal anneal to create bubbles as reported in this work certainly dispute the notion that it is end of range damage that is responsible for bubble formation. It would seem apparent that any end of range damage would be present before and after the rapid thermal anneal, however, bubbles only formed after the annealing process. It has also been observed that without an HF surface treatment to remove the native oxide, the hydrogen injection and diffusion process is slowed when compared with an HF treated surface. It may be that the native oxide must be etched by the hydrogen beam before the hydrogen injection and diffusion can proceed.

Void formation in the form of bubbles occurs in single-crystal silicon with subsurface ion implanted boron when the silicon is injected with atomic hydrogen. These bubbles only occur when the boron in the silicon is activated in the silicon with a rapid thermal anneal which is typically accomplished at 900° C. for thirty seconds. It should be recognized that without such an activation process bubbles are not produced. The teachings of the present invention have quantified doses of boron that are required to produce these voids in single-crystal silicon. It has recently been found that from approximately 3×10¹⁶ to 5×10¹⁶ hydrogen atoms per cm² are required to produce voids such as bubbles and platelets in the presence of boron.

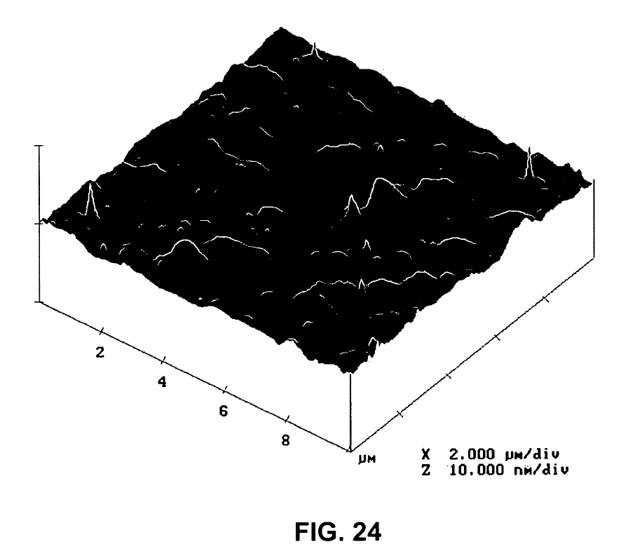

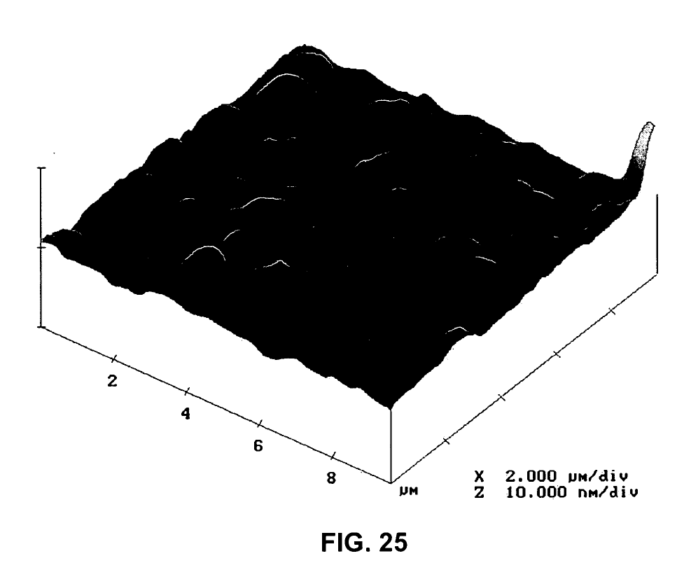

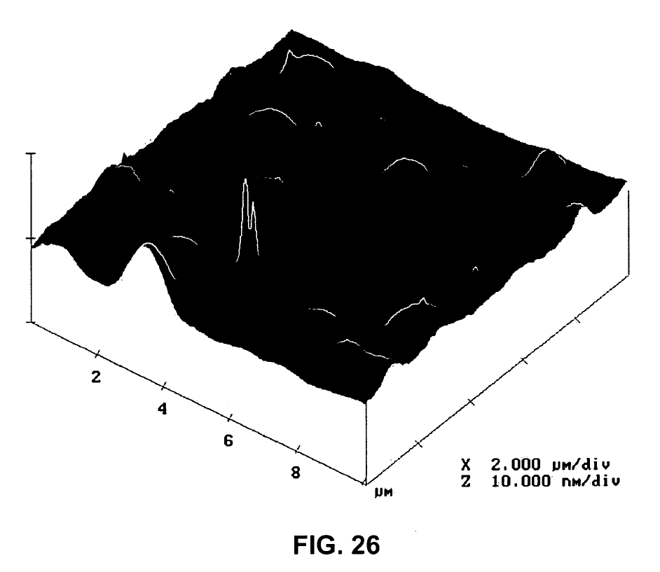

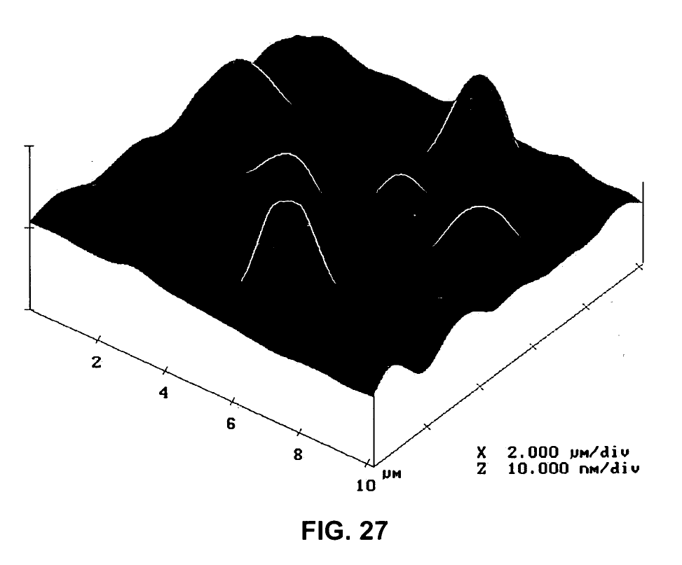

FIG. 24 through FIG. 27 illustrate hydrogen bubbling as a function of different boron doses. Each image is of a 10 μm×10 μm sample portion with a vertical scale of 10 nm. FIG. 24 is sample 60 given a dose of 1×10¹⁵ per cm² having a RMS surface value of 0.581, wherein no bubbles or other voids are visible in the micrograph. FIG. 25 is sample 61 given a dose of 2×10¹⁵ per cm² having a RMS surface value of 0.560, wherein surface disruptions appear but without full bubble development. FIG. 26 is sample 68 given a dose of 5×10¹⁵ per cm² having a RMS surface value of 0.772, wherein small bubbles begin to form across the entire surface. FIG. 27 is sample 48 given a dose of 1×10¹⁶ per cm² having a RMS surface value of 2.126, wherein full bubble development is evident. Based on the doses of hydrogen required to produce voids, activated boron appears to capture between six and ten hydrogen atoms per boron atom present, but not as many as the fifteen to twenty five hydrogen atoms which are present per boron atom. Furthermore, the absence of bubbles with no activation substantiates that the end of range damage does not capture sufficient hydrogen to create voids that result in bubbles.

Although the description above contains many details, these should not be construed as limiting the scope of the invention but as merely providing illustrations of some of the presently preferred embodiments of this invention. Therefore, it will be appreciated that the scope of the present invention fully encompasses other embodiments which may become obvious to those skilled in the art, and that the scope of the present invention is accordingly to be limited by nothing other than the appended claims, in which reference to an element in the singular is not intended to mean “one and only one” unless explicitly so stated, but rather “one or more.” All structural, chemical, and functional equivalents to the elements of the above-described preferred embodiment that are known to those of ordinary skill in the art are expressly incorporated herein by reference and are intended to be encompassed by the present claims. Moreover, it is not necessary for a device or method to address each and every problem sought to be solved by the present invention, for it to be encompassed by the present claims. Furthermore, no element, component, or method step in the present disclosure is intended to be dedicated to the public regardless of whether the element, component, or method step is explicitly recited in the claims. No claim element herein is to be construed under the provisions of 35 U.S.C. 112, sixth paragraph, unless the element is expressly recited using the phrase “means for.”

TABLE 1
Low Temperature Diffusion Calculations

| | | | | | | | |
|---|---|---|---|---|---|---|---|
| run # | T C | D cm²/sec | flux/cm²/sec | L cm | t sec | min | hours |

Time for Injection, diffusion, collection of critical dose through
distance L at temp Tc Based on Literature and M. Finnis diffusion calculator

| | | | | | | | |
|---|---|---|---|---|---|---|---|
| 1D av, flx low | 350 | 1.78E−08 | 1.00E+16 | 0.05 | 866,047 | 14434.12 | 240.57 |
| 1D hi, flx low | 350 | 1.78E−07 | 1.00E+16 | 0.05 | 86,605 | 1443.42 | 24.06 |
| 1D low, flx med | 350 | 1.78E−09 | 5.00E+16 | 0.05 | | | |
| 1D av, flx med | 350 | 1.78E−08 | 5.00E+16 | 0.05 | 203,353 | 3389.22 | 56.49 |
| 1D hi, flx med | 350 | 1.78E−07 | 5.00E+16 | 0.05 | 20,072 | 334.53 | 5.58 |
| 1D low, flx high | 350 | 1.78E−09 | 1.00E+17 | 0.05 | | | |
| 1D av, flx high | 350 | 1.78E−08 | 1.00E+17 | 0.05 | 127,425 | 2123.75 | 35.40 |
| 1D hi, flx high | 350 | 1.78E−07 | 1.00E+17 | 0.05 | 11,529 | 192.15 | 3.20 |
| 2D low, flx low | 375 | 2.82E−09 | 1.00E+16 | 0.05 | | | |
| 2D av, flx low | 375 | 2.82E−08 | 1.00E+16 | 0.05 | 552,064 | 9201.07 | 153.35 |
| 2D hi, flx low | 375 | 2.82E−07 | 1.00E+16 | 0.05 | 55,583 | 926.38 | 15.44 |
| 2D low, flx med | 375 | 2.82E−09 | 5.00E+16 | 0.05 | | | |
| 2D av, flx med | 375 | 2.82E−08 | 5.00E+16 | 0.05 | 131,058 | 2184.30 | 36.41 |
| 2D hi, flx med | 375 | 2.82E−07 | 5.00E+16 | 0.05 | 12,618 | 210.30 | 3.51 |
| 2D low, flx high | 375 | 2.82E−09 | 1.00E+17 | 0.05 | | | |
| 2D av, flx high | 375 | 2.82E−08 | 1.00E+17 | 0.05 | 75,516 | 1258.60 | 20.98 |
| 2D hi, flx high | 375 | 2.82E−07 | 1.00E+17 | 0.05 | 7,207 | 120.12 | 2.00 |
| 3D low, flx low | 400 | 4.10E−09 | 1.00E+16 | 0.05 | | | |
| 3D av, flx low | 400 | 4.10E−08 | 1.00E+16 | 0.05 | 379,786 | 6329.77 | 105.50 |
| 3D hi, flx low | 400 | 4.10E−07 | 1.00E+16 | 0.05 | 38,024 | 633.73 | 10.56 |
| 3D low, flx med | 400 | 4.10E−09 | 5.00E+16 | 0.05 | | | |
| 3D av, flx med | 400 | 4.10E−08 | 5.00E+16 | 0.05 | 85,566 | 1426.10 | 23.77 |
| 3D hi, flx med | 400 | 4.10E−07 | 5.00E+16 | 0.05 | 8,640 | 144.00 | 2.40 |
| 3D low, flx high | 400 | 4.10E−09 | 1.00E+17 | 0.05 | | | |
| 3D av, flx high | 400 | 4.10E−08 | 1.00E+17 | 0.05 | 49,875 | 831.25 | 13.85 |
| 3D hi, flx high | 400 | 4.10E−07 | 1.00E+17 | 0.05 | 4,987 | 83.12 | 1.39 |
| 4D low, flx low | 425 | 6.79E−09 | 1.00E+16 | 0.05 | | | |
| 4D av, flx low | 425 | 6.79E−08 | 1.00E+16 | 0.05 | 227,034 | 3783.90 | 63.07 |
| 4D hi, flx low | 425 | 6.79E−07 | 1.00E+16 | 0.05 | 22,703 | 378.38 | 6.31 |
| 4D low, flx med | 425 | 6.79E−09 | 5.00E+16 | 0.05 | 503,038 | 8383.97 | 139.73 |
| 4D av, flx med | 425 | 6.79E−08 | 5.00E+16 | 0.05 | 50,304 | 838.40 | 13.97 |
| 4D hi, flx med | 425 | 6.79E−07 | 5.00E+16 | 0.05 | 5,030 | 83.83 | 1.40 |
| 4D low, flx high | 425 | 6.79E−09 | 1.00E+17 | 0.05 | | | |
| 4D av, flx high | 425 | 6.79E−08 | 1.00E+17 | 0.05 | 28,166 | 469.43 | 7.82 |
| 4D hi, flx high | 425 | 6.79E−07 | 1.00E+17 | 0.05 | 2,821 | 47.02 | 0.78 |

But, at higher temperatures above 1000 C, where D is ˜0.5 cm/sec the time is reduced to:

| | | | | | |
|---|---|---|---|---|---|
| 4D low, med high | 900 | 5.00E−05 | 5.00E+16 | 0.05 | 70 |
| 4D av, flx med | 1000 | 8.00E−05 | 5.00E+16 | 0.05 | 45 |
| 4D hi, flx high | 1160 | 1.00E−04 | 5.00E+16 | 0.05 | 35 |

times for thicknesses less than full wafer thickness

| | | | | | | | |
|---|---|---|---|---|---|---|---|
| 1D low, flx low | 350 | 1.78E−09 | 1.00E+16 | 1.00E−02 | | | |
| 1D av, flx low | 350 | 1.78E−08 | 1.00E+16 | 1.00E−02 | 169,473 | 2824.55 | 47.08 |
| 1D hi, flx low | 350 | 1.78E−07 | 1.00E+16 | 1.00E−02 | 16,912 | 281.87 | 4.70 |
| 1D low, flx med | 350 | 1.78E−09 | 5.00E+16 | 1.00E−02 | 346,418 | 5773.63 | 96.23 |
| 1D av, flx med | 350 | 1.78E−08 | 5.00E+16 | 1.00E−02 | 34,642 | 577.37 | 9.62 |
| 1D hi, flx med | 350 | 1.78E−07 | 5.00E+16 | 1.00E−02 | 3,464 | 57.73 | 0.96 |
| 1D low, flx high | 350 | 1.78E−09 | 1.00E+17 | 1.00E−02 | 177,879 | 2964.65 | 49.41 |
| 1D av, flx high | 350 | 1.78E−08 | 1.00E+17 | 1.00E−02 | 17,788 | 296.47 | 4.94 |
| 1D hi, flx high | 350 | 1.78E−07 | 1.00E+17 | 1.00E−02 | 1,779 | 29.65 | 0.49 |
| 2D low, flx low | 375 | 2.82E−09 | 1.00E+16 | 1.00E−02 | 1,069,725 | 17828.75 | 297.15 |
| 2D av, flx low | 375 | 2.82E−08 | 1.00E+16 | 1.00E−02 | 106,973 | 1782.88 | 29.71 |
| 2D hi, flx low | 375 | 2.82E−07 | 1.00E+16 | 1.00E−02 | 10,700 | 178.33 | 2.97 |
| 2D low, flx med | 375 | 2.82E−09 | 5.00E+16 | 1.00E−02 | 218,661 | 3644.35 | 60.74 |
| 2D av, flx med | 375 | 2.82E−08 | 5.00E+16 | 1.00E−02 | 21,866 | 364.43 | 6.07 |
| 2D hi, flx med | 375 | 2.82E−07 | 5.00E+16 | 1.00E−02 | 2,187 | 36.45 | 0.61 |
| 2D low, flx high | 375 | 2.82E−09 | 1.00E+17 | 1.00E−02 | 112,278 | 1871.30 | 31.19 |
| 2D av, flx high | 375 | 2.82E−08 | 1.00E+17 | 1.00E−02 | 11,228 | 187.13 | 3.12 |
| 2D hi, flx high | 375 | 2.82E−07 | 1.00E+17 | 1.00E−02 | 1,123 | 18.72 | 0.31 |
| 3D low, flx low | 400 | 4.10E−09 | 1.00E+16 | 1.00E−02 | | | |
| 3D av, flx low | 400 | 4.10E−08 | 1.00E+16 | 1.00E−02 | 73,576 | 1226.27 | 20.44 |
| 3D hi, flx low | 400 | 4.10E−07 | 1.00E+16 | 1.00E−02 | 7,360 | 122.67 | 2.04 |
| 3D low, flx med | 400 | 4.10E−09 | 5.00E+16 | 1.00E−02 | 150,396 | 2506.60 | 41.78 |
| 3D av, flx med | 400 | 4.10E−08 | 5.00E+16 | 1.00E−02 | 15,040 | 250.67 | 4.18 |
| 3D hi, flx med | 400 | 4.10E−07 | 5.00E+16 | 1.00E−02 | 1,505 | 25.08 | 0.42 |
| 3D low, flx high | 400 | 4.10E−09 | 1.00E+17 | 1.00E−02 | 77,226 | 1287.10 | 21.45 |
| 3D av, flx high | 400 | 4.10E−08 | 1.00E+17 | 1.00E−02 | 7,723 | 128.72 | 2.15 |
| 3D hi, flx high | 400 | 4.10E−07 | 1.00E+17 | 1.00E−02 | 773 | 12.88 | 0.21 |
| 4D low, flx low | 425 | 6.79E−09 | 1.00E+16 | 1.00E−02 | 444,275 | 7404.58 | 123.41 |
| 4D av, flx low | 425 | 6.79E−08 | 1.00E+16 | 1.00E−02 | 44,429 | 740.48 | 12.34 |
| 4D hi, flx low | 425 | 6.79E−07 | 1.00E+16 | 1.00E−02 | 4,446 | 7.77 | 0.13 |
| 4D low, flx med | 425 | 6.79E−09 | 5.00E+16 | 1.00E−02 | 90,814 | 1513.56 | 25.23 |
| 4D av, flx med | 425 | 6.79E−08 | 5.00E+16 | 1.00E−02 | 9,081 | 151.36 | 2.52 |
| 40 hi, flx med | 425 | 6.79E−07 | 5.00E+16 | 1.00E−02 | 909 | 908.67 | 15.14 |
| 4D low, flx high | 425 | 6.79E−09 | 1.00E+17 | 1.00E−02 | 46,631 | 777.18 | 12.95 |
| 4D av, flx high | 425 | 6.79E−08 | 1.00E+17 | 1.00E−02 | 4,663 | 77.72 | 1.30 |
| 4D hi, flx high | 425 | 6.79E−07 | 1.00E+17 | 1.00E−02 | 466 | 7.77 | 0.13 |

But, at higher temperatures above 1000 C, where D is ˜0.5 cm/sec the time is reduced to:

| | | | | | |
|---|---|---|---|---|---|
| 4D low, med high | 900 | 5.00E−05 | 5.00E+16 | 1.00E−02 | 13.0 |
| 4D av, flx med | 1000 | 8.00E−05 | 5.00E+16 | 1.00E−02 | 8.3 |
| 4D hi, flx high | 1160 | 1.00E−04 | 5.00E+16 | 1.00E−02 | 6.8 |

linear estimate at very short distances

| | | | |
|---|---|---|---|
| 350 | 1.78E−08 | 1.00E+16 | 2.50E−05 |
| 350 | 1.78E−08 | 5.00E+16 | 2.50E−05 |
| 350 | 1.78E−08 | 1.00E+17 | 2.50E−05 |
| 350 | 1.78E−08 | 1.00E+16 | 5.00E−05 |
| 350 | 1.78E−08 | 5.00E+16 | 5.00E−05 |
| 350 | 1.78E−08 | 1.00E+17 | 5.00E−05 |
| 350 | 1.78E−07 | 1.00E+16 | 2.50E−05 |
| 350 | 1.78E−07 | 5.00E+16 | 2.50E−05 |
| 350 | 1.78E−07 | 1.00E+17 | 2.50E−05 |
| 350 | 1.78E−07 | 1.00E+16 | 5.00E−05 |
| 350 | 1.78E−07 | 5.00E+16 | 5.00E−05 |
| 350 | 1.78E−07 | 1.00E+17 | 5.00E−05 |
| 350 | 1.78E−09 | 1.00E+16 | 2.50E−05 |
| 350 | 1.78E−09 | 5.00E+16 | 2.50E−05 |
| 350 | 1.78E−09 | 1.00E+17 | 2.50E−05 |
| 350 | 1.78E−09 | 1.00E+16 | 5.00E−05 |
| 350 | 1.78E−09 | 5.00E+16 | 5.00E−05 |
| 350 | 1.78E−09 | 1.00E+17 | 5.00E−05 |

What is claimed is:

1. A multilayered material for fabrication of a nanodevice, comprising:
(a) a device layer; and
(b) a substrate layer adjacent said device layer;
(c) wherein said substrate layer comprises a diffusion layer having a collection region adapted for capture of hydrogen.

2. A material as recited in claim 1, wherein said substrate layer further comprises an insulator layer between said device layer and said diffusion layer.

3. A material as recited in claim 1, wherein said collection region is a heavily doped region for capture of hydrogen.

4. A material as recited in claim 1, wherein said collection region is a getter/acceptor region for capture of hydrogen.

5. A material as recited in claim 1, wherein said device layer comprises a material having at least a portion that has been optimized for fabricating said nanodevice.

6. A material as recited in claim 2, wherein said insulator layer comprises a material that provides a high degree of electrical and thermal insulation between the diffusion layer and the device layer.

7. A material as recited in claim 1, wherein said diffusion layer comprises a material optimized for a high rate of diffusion of hydrogen therethrough.

8. A multilayered material for fabrication of a nanodevice, comprising:
(a) a device layer; and
(b) a substrate layer adjacent said device layer;
(c) wherein said substrate layer comprises a diffusion layer having a collection region adapted for capture of hydrogen;
(d) wherein said substrate layer further comprises an insulator layer between said device layer and said diffusion layer.

9. A material as recited in claim 8, wherein said collection region is a heavily doped region for capture of hydrogen.

10. A material as recited in claim 8, wherein said collection region is a getter/acceptor region for capture of hydrogen.

11. A material as recited in claim 8, wherein said device layer comprises a material having at least a portion that has been optimized for fabricating said nanodevice.

12. A material as recited in claim 8, wherein said insulator layer comprises a material that provides a high degree of electrical and thermal insulation between the diffusion layer and the device layer.

13. A material as recited in claim 8, wherein said diffusion layer comprises a material optimized for a high rate of diffusion of hydrogen therethrough.

14. A multilayered material for use in fabrication of a nanodevice, comprising:
(a) a device layer;
(b) an insulator layer adjacent said device layer; and
(c) a diffusion layer having a collection region adapted for capture of hydrogen adjacent said insulator layer.

15. A material as recited in claim 14, wherein said collection region is a heavily doped region for capture of hydrogen.

16. A material as recited in claim 14, wherein said collection region is a getter/acceptor region for capture of hydrogen.

17. A material as recited in claim 14, wherein said device layer comprises a material having at least a portion that has been optimized for fabricating said nanodevice.

18. A material as recited in claim 14, wherein said insulator layer comprises a material that provides a high degree of electrical and thermal insulation between the diffusion layer and the device layer.

19. A material as recited in claim 14, wherein said diffusion layer comprises a material optimized for a high rate of diffusion of hydrogen therethrough.

20. A multilayered material for use in fabrication of a nanodevice, comprising:
(a) a layer of material for device fabrication;
(b) a layer of insulator material; and
(c) a layer of material though which hydrogen can diffuse at a high rate and having a collection region adapted for capture of hydrogen;
(d) wherein said layer of insulator material is disposed between said layer of material for device fabrication and said collection region.

21. A material as recited in claim 20, wherein said collection region is a heavily doped region for capture of hydrogen.

22. A material as recited in claim 20, wherein said diffusion layer has a getter/acceptor region for capture of hydrogen.

23. A material as recited in claim 20, wherein said device layer comprises a material having at least a portion that has been optimized for fabricating said nanodevice.

24. A material as recited in claim 20, wherein said insulator layer provides a high degree of electrical and thermal insulation between the diffusion layer and the device layer.

25. A material as recited in claim 20, wherein said diffusion layer comprises a material optimized for a high rate of diffusion of hydrogen therethrough.

26. A multilayered material for use in fabrication of a nanodevice, comprising:
(a) a layer of material for device fabrication, said material having at least a portion that has been optimized for fabricating said nanodevice;
(b) a layer of material though which hydrogen can diffuse at a high rate and having a collection region adapted for capture of hydrogen, said collection region comprising a heavily doped region or a getter/acceptor region;
(c) wherein said diffusion layer comprises a material optimized for a high rate of diffusion of hydrogen therethrough; and
(d) a layer of insulator material, wherein said insulator layer provides a high degree of electrical and thermal insulation between the diffusion layer and the device layer;
(e) wherein the insulator layer is disposed between the device layer and the diffusion layer.

27. A material as recited in claim 1, 8, 14, 20 or 26, further comprising at least one heat dissipation layer.

28. A material as recited in claim 1, 8, 14, 20 or 26, further comprising at least one RF shield layer.

29. A method of fabricating a multilayered material for use in making a nanodevice, comprising:
providing a wafer having at least a portion that has been optimized for making said nanodevice;
implanting said wafer with hydrogen to a depth associated with a thickness to remain after an ion cut; and
bonding said wafer to a substrate layer;
said substrate layer comprising a diffusion layer having a collection region adapted for capture of hydrogen.

30. A method as recited in claim 29, wherein said substrate layer further comprises an insulator layer bonded to said diffusion layer.

31. A method as recited in claim 29, wherein said collection region is a heavily doped region for capture of hydrogen.

32. A method as recited in claim 29, wherein said collection region is a getter/acceptor region for capture of hydrogen.

33. A method as recited in claim 29, further comprising ion cutting said wafer so as to leave a device layer bonded to the substrate layer.

34. A method as recited in claim 30, wherein said substrate layer is formed according to the steps comprising:
creating hydrogen getters in said collection region; and
bonding the insulator layer to a surface of the diffusion layer adjacent the collection region.

35. A method as recited in claim 30, wherein said substrate layer is formed according to the steps comprising:
bonding the insulator layer to a surface of the diffusion layer adjacent the collection region; and
creating hydrogen getters in said collection region beneath said insulator layer.

36. A method as recited in claim 29, further comprising ion cutting said wafer so as to leave a device layer bonded to the substrate layer.

37. A method as recited in claim 36, further comprising:
planarizing said device layer;
bonding said device layer to a 3-d stack or handle;
injecting and diffusing hydrogen into said collection region; and
ion cutting said diffusion layer at said collection region; and
removing said remaining diffusion layer and insulator layer.

38. A method of fabricating a multilayered material for use in making a nanodevice, comprising:
providing a wafer having at least a portion that has been optimized for making said nanodevice;
implanting said wafer with hydrogen to a depth associated with a thickness to remain after an ion cut; and
bonding said wafer to a substrate layer;
said substrate layer comprising a diffusion layer having a collection region adapted for capture of hydrogen;
said substrate comprising an insulator layer bonded to said diffusion layer.

39. A method as recited in claim 38, wherein said collection region is a heavily doped region for capture of hydrogen.

40. A method as recited in claim 38, wherein said collection region is a getter/acceptor region for capture of hydrogen.

41. A method as recited in claim 38, further comprising ion cutting said wafer so as to leave a device layer bonded to the substrate layer.

42. A method as recited in claim 38, wherein said substrate layer is formed according to the steps comprising:
creating hydrogen getters in said collection region; and
bonding the insulator layer to a surface of the diffusion layer adjacent the collection region.

43. A method as recited in claim 38, wherein said substrate layer is formed according to the steps comprising:
bonding the insulator layer to a surface of the diffusion layer adjacent the collection region; and
creating hydrogen getters in said collection region beneath said insulator layer.

44. A method as recited in claim 38, further comprising:
planarizing said device layer;
bonding said device layer to a 3-d stack or handle;
injecting and diffusing hydrogen into said collection region; and
ion cutting said diffusion layer at said collection region; and
removing said remaining diffusion layer and insulator layer.

45. A method of fabricating a multilayered material for use in making a nanodevice, comprising:
providing a wafer having at least a portion that has been optimized for making said nanodevice;
implanting said wafer with hydrogen to a depth associated with a thickness to remain after an ion cut;
bonding said wafer to a substrate layer;
said substrate layer comprising a diffusion layer having a collection region adapted for capture of hydrogen;
said substrate layer comprising an insulator layer bonded to said diffusion layer; and
ion cutting said wafer so as to leave a device layer bonded to the substrate layer.

46. A method as recited in claim 45, wherein said collection region is a heavily doped region for capture of hydrogen.

47. A method as recited in claim 45, wherein said collection region is a getter/acceptor region for capture of hydrogen.

48. A method as recited in claim 45, further comprising ion cutting said wafer so as to leave a device layer bonded to the substrate layer.

49. A method as recited in claim 45, wherein said substrate layer is formed according to the steps comprising:
creating hydrogen getters in said collection region; and
bonding the insulator layer to a surface of the diffusion layer adjacent the collection region.

50. A method as recited in claim 45, wherein said substrate layer is formed according to the steps comprising:
bonding the insulator layer to a surface of the diffusion layer adjacent the collection region; and
creating hydrogen getters in said collection region beneath said insulator layer.

51. A method as recited in claim 45, further comprising:
planarizing said device layer;
bonding said device layer to a 3-d stack or handle;
injecting and diffusing hydrogen into said collection region; and
ion cutting said diffusion layer at said collection region; and
removing said remaining diffusion layer and insulator layer.

52. A method of fabricating a multilayered material for use in making a nanodevice, comprising:
providing a wafer having at least a portion that has been optimized for making said nanodevice;
implanting said wafer with hydrogen to a depth associated with a thickness to remain after an ion cut;
forming a diffusion layer having a region for collecting hydrogen;
bonding said diffusion layer to an insulator layer;
bonding said insulator layer to said wafer; and
ion cutting said wafer so as to leave a device layer bonded to the substrate layer.

53. A method as recited in claim 52, wherein said collection region is a heavily doped region for capture of hydrogen.

54. A method as recited in claim 52, wherein said collection region is a getter/acceptor region for capture of hydrogen.

55. A method as recited in claim 52, wherein said substrate layer is formed according to the steps comprising:
creating hydrogen getters in said collection region; and
bonding the insulator layer to a surface of the diffusion layer adjacent the collection region.

56. A method as recited in claim 52, wherein said substrate layer is formed according to the steps comprising:
bonding the insulator layer to a surface of the diffusion layer adjacent the collection region; and
creating hydrogen getters in said collection region beneath said insulator layer.

57. A method as recited in claim 52, further comprising:
planarizing said device layer;
bonding said device layer to a 3-d stack or handle;
injecting and diffusing hydrogen into said collection region; and
ion cutting said diffusion layer at said collection region; and
removing said remaining diffusion layer and insulator layer.

58. A method of fabricating a multilayered material for use in making a nanodevice, comprising:
providing a wafer having at least a portion that has been optimized for making said nanodevice;
implanting said wafer with hydrogen to a depth associated with a thickness to remain after an ion cut;
forming a diffusion layer having a region for collecting hydrogen;
bonding said diffusion layer to an insulator layer;
bonding said insulator layer to said wafer;
ion cutting said wafer so as to leave a device layer bonded to the substrate layer; and
planarizing said device layer.

59. A method as recited in claim 58, wherein said collection region is a heavily doped region for capture of hydrogen.

60. A method as recited in claim 58, wherein said collection region is a getter/acceptor region for capture of hydrogen.

61. A method as recited in claim 58, wherein said substrate layer is formed according to the steps comprising:
creating hydrogen getters in said collection region; and
bonding the insulator layer to a surface of the diffusion layer adjacent the collection region.

62. A method as recited in claim 58, wherein said substrate layer is formed according to the steps comprising:
bonding the insulator layer to a surface of the diffusion layer adjacent the collection region; and
creating hydrogen getters in said collection region beneath said insulator layer.

63. A method as recited in claim 58, further comprising:
bonding said device layer to a 3-d stack or handle;
injecting and diffusing hydrogen into said collection region; and
ion cutting said diffusion layer at said collection region; and
removing said remaining diffusion layer and insulator layer.

64. A method of fabricating a nanodevice, comprising:
providing a wafer having at least a portion that has been optimized for making said nanodevice;
implanting said wafer with hydrogen to a depth associated with a thickness to remain after an ion cut;
forming a diffusion layer having a region for collecting hydrogen;
bonding said diffusion layer to an insulator layer;
bonding said insulator layer to said wafer;
ion cutting said wafer so as to leave a device layer bonded to the substrate layer;
planarizing said device layer;
bonding said device layer to a 3-d stack or handle;
injecting and diffusing hydrogen into said collection region; and
ion cutting said diffusion layer at said collection region.

65. A method as recited in claim 64, wherein said collection region is a heavily doped region for capture of hydrogen.

66. A method as recited in claim 64, wherein said collection region is a getter/acceptor region for capture of hydrogen.

67. A method as recited in claim 64, wherein said substrate layer is formed according to the steps comprising:
creating hydrogen getters in said collection region; and
bonding the insulator layer to a surface of the diffusion layer adjacent the collection region.

68. A method as recited in claim 64, wherein said substrate layer is formed according to the steps comprising:
bonding the insulator layer to a surface of the diffusion layer adjacent the collection region; and
creating hydrogen getters in said collection region beneath said insulator layer.

69. A method as recited in claim 64, further comprising:
removing said remaining diffusion layer and insulator layer.

70. A method of fabricating a nanodevice, comprising:
providing a wafer having at least a portion that has been optimized for making said nanodevice;
implanting said wafer with hydrogen to a depth associated with a thickness to remain after an ion cut;
bonding a diffusion layer to an insulator layer;
said diffusion layer having a region for collecting hydrogen;
bonding said insulator layer to said wafer;
ion cutting said wafer so as to leave a device layer bonded to the substrate layer;
planarizing said device layer;
bonding said device layer to a 3-d stack or handle;
injecting and diffusing hydrogen into said heavily doped region;
ion cutting said diffusion layer at said heavily doped region; and
removing said remaining diffusion layer and insulator layer.

71. A method as recited in claim 70, wherein said collection region is a heavily doped region for capture of hydrogen.

72. A method as recited in claim 70, wherein said collection region is a getter/acceptor region for capture of hydrogen.

73. A method as recited in claim 70, further comprising ion cutting said wafer so as to leave a device layer bonded to the substrate layer.

74. A method as recited in claim 70, wherein said substrate layer is formed according to the steps comprising:
creating hydrogen getters in said collection region; and
bonding the insulator layer to a surface of the diffusion layer adjacent the collection region.

75. A method as recited in claim 70, wherein said substrate layer is formed according to the steps comprising:
bonding the insulator layer to a surface of the diffusion layer adjacent the collection region; and
creating hydrogen getters in said collection region beneath said insulator layer.

76. A method as recited in claim 34, 35, 42, 43, 49, 50, 55, 56, 61, 62, 67, 68, 74 or 75, wherein said hydrogen getters are created by atomic injection.

77. A method as recited in claim 34, 35, 42, 43, 49, 50, 55, 56, 61, 62, 67, 68, 74 or 75, wherein said hydrogen getters are created by plasma injection.

78. A method as recited in claim 34, 35, 42, 43, 49, 50, 55, 56, 61, 62, 67, 68, 74 or 75, wherein said hydrogen getters are created by injection from a solid source adjacent said diffusion layer.

79. A method as recited in claim 34, 35, 42, 43, 49, 50, 55, 56, 61, 62, 67, 68, 74 or 75, further comprising pulse heating said diffusion layer during injection of hydrogen getters.

80. A method as recited in claim 29, 38, 45, 52, 58, 64 or 70, further comprising forming vias and metallization to connect two or more said layers.
